(19) United States
(12) Patent Application Publication
(10) Pub. No.: US 2016/0070096 A1
(43) Pub. Date: Mar. 10, 2016

(54) APERTURE PLATE PERIMETER ROUTING USING ENCAPSULATED SPACER CONTACT

(71) Applicant: Pixtronix, Inc., San Diego, CA (US)

(72) Inventors: Teruo Sasagawa, Los Gatos, CA (US); Jasper Lodewyk Steyn, Cupertino, CA (US); Patrick Forrest Brinkley, San Mateo, CA (US); Matthew Brian Sampsell, Chicago, IL (US); Wilhelmus Adrianus de Groot, Palo Alto, CA (US)

(21) Appl. No.: 14/478,845

(22) Filed: Sep. 5, 2014

(51) Int. Cl. G02B 26/02; B81B 7/02; G09G 3/34

(52) U.S. Cl. CPC G02B 26/02; G09G 3/3433; B81B 7/02; B81B 2201/047; B81B 2207/053; B81B 2207/07

(57) ABSTRACT

This disclosure provides systems, methods and apparatus for locating at least a portion of the routing interconnects on the aperture plate to reduce or completely eliminate bezel space, reduce line resistance, reduce line capacitance and increase power savings. In some implementations, one aspect, the routing interconnects may electrically connect row interconnects from an array of pixels to a row voltage driver. In some implementations, a conductive spacer may be coupled between an aperture plate and a light modulator substrate and may electrically connect at least one row interconnect on the light modulator substrate to at least one routing interconnect on the aperture plate. Some or all of the routing interconnects may run through the display area of the electromechanical device. Some or all of the conductive spacers may make contact with a row interconnect and a routing interconnected within the display area, for example via a conductive contact pad.

### TECHNICAL FIELD

This disclosure relates to the field of displays, and particularly to displays with movable electromechanical system elements, and methods for operating the same.

### DESCRIPTION OF THE RELATED TECHNOLOGY

Electromechanical systems (EMS) include devices having electrical and mechanical elements, actuators, transducers, sensors, optical components such as mirrors and optical films, and electronics. EMS devices or elements can be manufactured at a variety of scales including, but not limited to, microscales and nanoscales. For example, microelectromechanical systems (MEMS) devices can include structures having sizes ranging from about a micron to hundreds of microns or more. Nanoelectromechanical systems (NEMS) devices can include structures having sizes smaller than a micron including, for example, sizes smaller than several hundred nanometers. Electromechanical elements may be created using deposition, etching, lithography, and/or other micromachining processes that etch away parts of substrates and/or deposited material layers, or that add layers to form electrical and electromechanical devices.

In a conventional digital microelectromechanical shutter (DMS) display, a plurality of MEMS DMS light modulators are laid out in an array. Each shutter is capable of blocking or passing light by moving over or away from an aperture. Each shutter and aperture acts as a pixel in the display, making up the screen or viewable portion of the display. The bezel area is the area of the display that surrounds the viewable portion of the display (also known as the “display area”). The bezel area includes routing lines and other electronics for controlling the display device. The operation of the shutters is controlled by an actuator which moves the shutters to block or pass light and thereby create an image on the display. Conventional MEMS DMS require a large number of routing lines to achieve a high pixel density (high pixels per inch (PPI)). However, because of display fabrication process limits (such as photo resolution, line resistance, and/or material resistivity), conventional high PPI displays require a wide bezel area in order to include space for the routing lines. Wide bezel areas make display devices bulky and reduce available real estate for a display area.

### SUMMARY

The systems, methods and devices of this disclosure each have several innovative aspects, no single one of which is solely responsible for the desirable attributes disclosed herein.

One innovative aspect of the subject matter described in this disclosure can be implemented in a display including a substrate having a plurality of pixels, each respective pixel including: at least one light modulator, at least one row interconnect, at least one column interconnect, an aperture plate including at least one routing interconnect formed thereon, and a conductive spacer coupled between the substrate and the aperture plate, the conductive spacer being in electrical connection between the at least one row interconnect and the at least one routing interconnect. In some implementations, the substrate can include at least one routing interconnect. In some implementations, each of the at least one routing interconnects can be formed on the aperture plate.

In some implementations, the display can include a bezel area, wherein the at least one routing interconnect runs through the bezel area. In some implementations, the conductive spacer can make electrical contact with the at least one routing interconnect in the bezel area.

In some implementations, the display can include a display area, wherein the at least one routing interconnect runs through the display area. In some implementations, the conductive spacer can make electrical contact with the at least one routing interconnect in the display area. In some implementations, at least one row interconnect can be formed on the aperture plate.

In some implementations, the at least one row interconnect can be electrically coupled to a row driver, and at least one column interconnect can be electrically coupled to a column driver. In some implementations, the routing interconnect can electrically couple the at least one row interconnect to the row driver. In some implementations, the routing interconnect can electrically couple the at least one column interconnect to the column driver. In some implementations, the routing interconnect can electrically couple the at least one row interconnect to at least one other row interconnect. In some implementations, the routing interconnect can electrically couple the at least one column interconnect to at least one other column interconnect.

In some implementations, the aperture plate can include at least one of an elastic polymer and a eutectic metal. In some implementations, the conductive spacer includes a flexible contact. In some implementations, a respective pixel can include at least two conductive spacers. In some implementations, the light modulator can be a MEMS light modulator.

In some implementations, the display can include: a display, a processor that is capable of communicating with the display, the processor being capable of processing image data, and a memory device that is capable of communicating with the processor. In some implementations, the display can include a driver circuit capable of sending at least one signal to the display, and a controller capable of sending at least a portion of the image data to the driver circuit. In some implementations, the display can include an image source module capable of sending the image data to the processor, wherein the image source module can include at least one of a receiver, transceiver, and transmitter. In some implementations, the display can include an input device capable of receiving input data and to communicate the input data to the processor.

Another innovative aspect of the subject matter described in this disclosure can be implemented in a display, including a substrate having a plurality of pixels, each respective pixel can include: at least one means for modulating light, at least one means for electrically connecting a row of pixels, at least one means for electrically connecting a column of pixels, an aperture plate means including at least one means for routing an electrical signal formed thereon, and a conductive spacer means coupled between the substrate and the aperture plate means, the conductive spacer being in electrical connection between the at least one means for electrically connecting a row of pixels and the at least one means for routing an electrical signal.

In some implementations, the substrate can include at least one means for routing an electrical signal. In some implementations, the at least one means for electrically connecting a row of pixels can be electrically coupled to a means for providing a drive voltage and at least one means for electrically connecting a column of pixels can be electrically coupled to the means for providing a drive voltage. In some implementations, the aperture plate can include at least one means for improving contact between the conductive spacer means and the means for routing an electrical signal. In some implementations, the conductive spacer means can include at least one flexible contact means. In some implementations, a respective pixel can include at least two conductive spacer means. In some implementations, the means for modulating light can be a MEMS light modulator.

Details of one or more implementations of the subject matter described in this disclosure are set forth in the accompanying drawings and the description below. Other features, aspects, and advantages will become apparent from the description, the drawings and the claims. Note that the relative dimensions of the following figures may not be drawn to scale.

### BRIEF DESCRIPTION OF THE DRAWINGS

FIG. 1A shows a schematic diagram of an example direct-view microelectromechanical systems (MEMS)-based display apparatus.

FIG. 1B shows a block diagram of an example host device.

FIGS. 2A and 2B show views of an example dual actuator shutter assembly.

FIG. 3 shows a schematic diagram of an example control matrix suitable for controlling the light modulators of the display apparatus of FIG. 1A.

FIG. 4A shows a cross-sectional view of an example MEMS-up implementation of a shutter-based display apparatus.

FIG. 4B shows a cross-sectional view of an example MEMS-down implementation of a shutter-based display apparatus.

FIG. 5 shows a cross-sectional view of an example display apparatus illustrating routing interconnects on the substrate and the aperture plate.

FIG. 6A shows a plan view of an example display apparatus illustrating row, column and routing interconnects for an array of pixels.

FIG. 6B shows an example display apparatus including a plan view and a cross-sectional view of the apparatus.

FIG. 7 shows a cross-sectional view of an example display apparatus illustrating routing interconnects running through the display area.

FIG. 8 shows a plan view of an example display apparatus illustrating row, column and routing interconnects.

FIG. 9 shows a cross-sectional view of an example display apparatus illustrating routing contacts in the display area.

FIG. 10 shows a plan view of an example display apparatus illustrating row, column and routing interconnects.

FIG. 11 shows a cross-sectional view of an example display apparatus illustrating a conductive spacer making an electrical connection between a substrate and an aperture plate.

FIG. 12 shows a cross-sectional view of an example display apparatus illustrating a conductive spacer making an electrical connection between a substrate and an aperture plate.

FIG. 13 shows a cross-sectional view of an example display apparatus illustrating a conductive spacer making an electrical connection between a substrate and an aperture plate.

FIG. 14 shows a cross-sectional view of an example display apparatus illustrating conductive spacers making an electrical connection between a substrate and an aperture plate.

FIGS. 15A and 15B show cross-sectional views of example display apparatuses illustrating conductive spacers making an electrical connection between a substrate and an aperture plate.

FIGS. 16A and 16B show system block diagrams of an example display device that includes a plurality of display elements.

Like reference numbers and designations in the various drawings indicate like elements.

### DETAILED DESCRIPTION

The following description is directed to certain implementations for the purposes of describing the innovative aspects of this disclosure. However, a person having ordinary skill in the art will readily recognize that the teachings herein can be applied in a multitude of different ways. The described implementations may be implemented in any device, apparatus, or system that is capable of displaying an image, whether in motion (such as video) or stationary (such as still images), and whether textual, graphical or pictorial. The concepts and examples provided in this disclosure may be applicable to a variety of displays, such as liquid crystal displays (LCDs), organic light-emitting diode (OLED) displays, field emission displays, and electromechanical systems (EMS) and microelectromechanical (MEMS)-based displays, in addition to displays incorporating features from one or more display technologies.

The described implementations may be included in or associated with a variety of electronic devices such as, but not limited to: mobile telephones, multimedia Internet enabled cellular telephones, mobile television receivers, wireless devices, smartphones, Bluetooth® devices, personal data assistants (PDAs), wireless electronic mail receivers, hand-held or portable computers, netbooks, notebooks, smartbooks, tablets, printers, copiers, scanners, facsimile devices, global positioning system (GPS) receivers/navigators, cameras, digital media players (such as MP3 players), camcorders, game consoles, wrist watches, wearable devices, clocks, calculators, television monitors, flat panel displays, electronic reading devices (such as e-readers), computer monitors, auto displays (such as odometer and speedometer displays), cockpit controls and/or displays, camera view displays (such as the display of a rear view camera in a vehicle), electronic photographs, electronic billboards or signs, projectors, architectural structures, microwaves, refrigerators, stereo systems, cassette recorders or players, DVD players, CD players, VCRs, radios, portable memory chips, washers, dryers, washer/dryers, parking meters, packaging (such as in electromechanical systems (EMS) applications including microelectromechanical systems (MEMS) applications, in addition to non-EMS applications), aesthetic structures (such as display of images on a piece of jewelry or clothing) and a variety of EMS devices.

The teachings herein also can be used in non-display applications such as, but not limited to, electronic switching devices, radio frequency filters, sensors, accelerometers, gyroscopes, motion-sensing devices, magnetometers, inertial components for consumer electronics, parts of consumer electronics products, varactors, liquid crystal devices, electrophoretic devices, drive schemes, manufacturing processes and electronic test equipment. Thus, the teachings are not intended to be limited to the implementations depicted solely in the Figures, but instead have wide applicability as will be readily apparent to one having ordinary skill in the art.

In some implementations described herein, an electromechanical device may be provided with at least a portion of the routing interconnects formed on the aperture plate to reduce or completely eliminate bezel space, reduce line resistance, reduce line capacitance and increase power savings. The electromechanical device may include some routing interconnects fabricated on the aperture plate, and some routing interconnects fabricated on the same substrate that light modulators are formed on. The routing interconnects may electrically connect row interconnects from an array of pixels to a row voltage driver. A conductive spacer may be coupled between an aperture plate and a light modulator substrate and may electrically connect at least one row interconnect on the light modulator substrate to at least one routing interconnect on the aperture plate. Some or all of the routing interconnects may run through the display area of the electromechanical device. Some or all of the conductive spacers may make contact with a row interconnect and a routing interconnected within the display area, for example via a conductive contact pad. Contact between the conductive spacer and the routing interconnect may be improved by using one or a combination of: an elastic polymer, a flexible contact and a eutectic metal.

Particular implementations of the subject matter described in this disclosure can be implemented to realize one or more of the following potential advantages. The systems and methods described herein may reduce power loss during operation of an electromechanical device by reducing resistance and capacitance of control interconnects. In addition, the systems and methods described herein may reduce the bezel area of a display device, thereby increasing possible display area and reducing the profile of a display device. Additionally, a more secure electrical and physical connection may be created between display control circuitry and routing interconnects. Furthermore, particular implementations of the subject matter described in this disclosure can lower routing resistance and capacitance and thereby reduce signal propagation delay and signal distortion and allow for faster update rates and an increased number of bitplanes. The reduction in signal delay can increase resolution and allow for greater size and screen shape resulting in a higher PPI screen with one side driver.

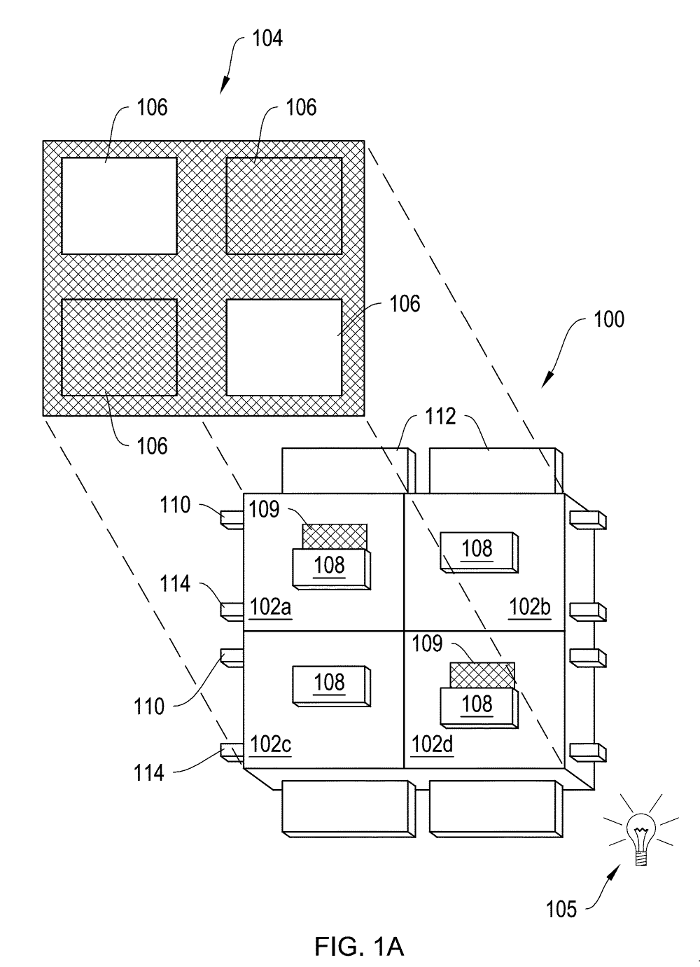

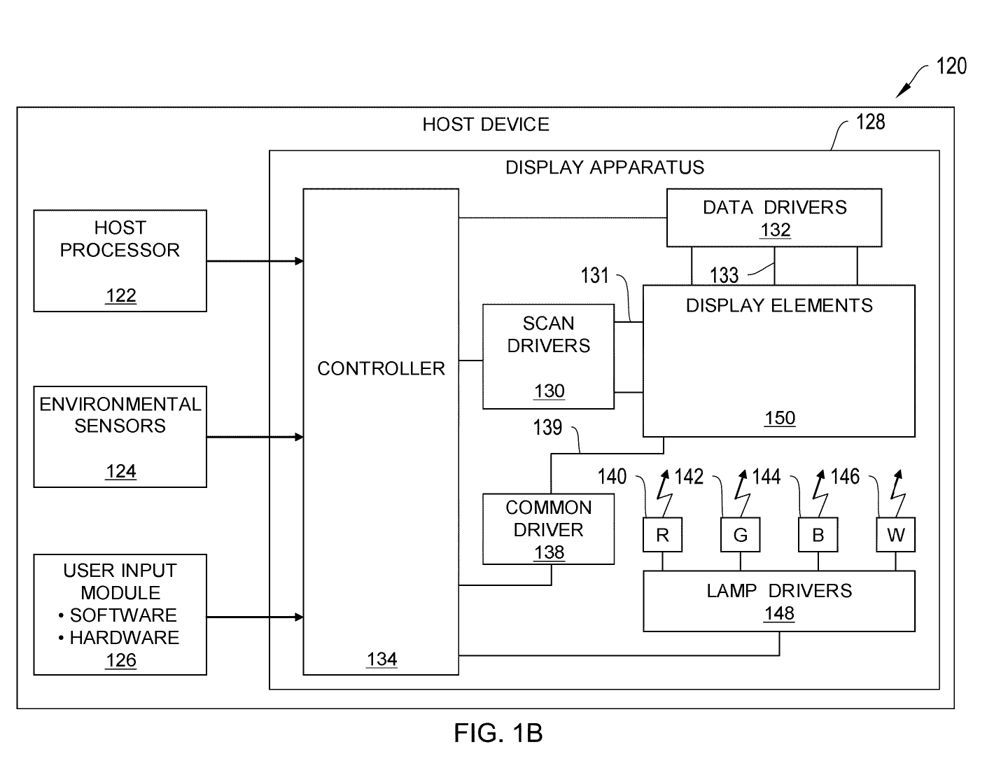

FIG. 1A shows a schematic diagram of an example direct-view MEMS-based display apparatus 100. The display apparatus 100 includes a plurality of light modulators 102a-102d (generally light modulators 102) arranged in rows and columns. In the display apparatus 100, the light modulators 102a and 102d are in the open state, allowing light to pass. The light modulators 102b and 102c are in the closed state, obstructing the passage of light. By selectively setting the states of the light modulators 102a-102d, the display apparatus 100 can be utilized to form an image 104 for a backlit display, if illuminated by a lamp or lamps 105. In another implementation, the apparatus 100 may form an image by reflection of ambient light originating from the front of the apparatus. In another implementation, the apparatus 100 may form an image by reflection of light from a lamp or lamps positioned in the front of the display, i.e., by use of a front light.

In some implementations, each light modulator 102 corresponds to a pixel 106 in the image 104. In some other implementations, the display apparatus 100 may utilize a plurality of light modulators to form a pixel 106 in the image 104. For example, the display apparatus 100 may include three color-specific light modulators 102. By selectively opening one or more of the color-specific light modulators 102 corresponding to a particular pixel 106, the display apparatus 100 can generate a color pixel 106 in the image 104. In another example, the display apparatus 100 includes two or more light modulators 102 per pixel 106 to provide a luminance level in an image 104. With respect to an image, a pixel corresponds to the smallest picture element defined by the resolution of image. With respect to structural components of the display apparatus 100, the term pixel refers to the combined mechanical and electrical components utilized to modulate the light that forms a single pixel of the image.

The display apparatus 100 is a direct-view display in that it may not include imaging optics typically found in projection applications. In a projection display, the image formed on the surface of the display apparatus is projected onto a screen or onto a wall. The display apparatus is substantially smaller than the projected image. In a direct view display, the image can be seen by looking directly at the display apparatus, which contains the light modulators and optionally a backlight or front light for enhancing brightness and/or contrast seen on the display.

Direct-view displays may operate in either a transmissive or reflective mode. In a transmissive display, the light modulators filter or selectively block light which originates from a lamp or lamps positioned behind the display. The light from the lamps is optionally injected into a lightguide or backlight so that each pixel can be uniformly illuminated. Transmissive direct-view displays are often built onto transparent substrates to facilitate a sandwich assembly arrangement where one substrate, containing the light modulators, is positioned over the backlight. In some implementations, the transparent substrate can be a glass substrate (sometimes referred to as a glass plate or panel), or a plastic substrate. The glass substrate may be or include, for example, a borosilicate glass, wine glass, fused silica, a soda lime glass, quartz, artificial quartz, Pyrex, or other suitable glass material. Each light modulator 102 can include a shutter 108 and an aperture 109. To illuminate a pixel 106 in the image 104, the shutter 108 is positioned such that it allows light to pass through the aperture 109. To keep a pixel 106 unlit, the shutter 108 is positioned such that it obstructs the passage of light through the aperture 109. The aperture 109 is defined by an opening patterned through a reflective or light-absorbing material in each light modulator 102.

The display apparatus also includes a control matrix coupled to the substrate and to the light modulators for controlling the movement of the shutters. The control matrix includes a series of electrical interconnects (such as interconnects 110, 112 and 114), including at least one write-enable interconnect 110 (also referred to as a scan line interconnect) per row of pixels, one data interconnect 112 for each column of pixels, and one common interconnect 114 providing a common voltage to all pixels, or at least to pixels from both multiple columns and multiples rows in the display apparatus 100. In response to the application of an appropriate voltage (the write-enabling voltage, V_{WE}), the write-enable interconnect 110 for a given row of pixels prepares the pixels in the row to accept new shutter movement instructions. The data interconnects 112 communicate the new movement instructions in the form of data voltage pulses. The data voltage pulses applied to the data interconnects 112, in some implementations, directly contribute to an electrostatic movement of the shutters. In some other implementations, the data voltage pulses control switches, such as transistors or other non-linear circuit elements that control the application of separate drive voltages, which are typically higher in magnitude than the data voltages, to the light modulators 102. The application of these drive voltages results in the electrostatic driven movement of the shutters 108.

The control matrix also may include, without limitation, circuitry, such as a transistor and a capacitor associated with each shutter assembly. In some implementations, the gate of each transistor can be electrically connected to a scan line interconnect. In some implementations, the source of each transistor can be electrically connected to a corresponding data interconnect. In some implementations, the drain of each transistor may be electrically connected in parallel to an electrode of a corresponding capacitor and to an electrode of a corresponding actuator. In some implementations, the other electrode of the capacitor and the actuator associated with each shutter assembly may be connected to a common or ground potential. In some other implementations, the transistor can be replaced with a semiconducting diode, or a metal-insulator-metal switching element.

FIG. 1B shows a block diagram of an example host device 120 (i.e., cell phone, smart phone, PDA, MP3 player, tablet, e-reader, netbook, notebook, watch, wearable device, laptop, television, or other electronic device). The host device 120 includes a display apparatus 128 (such as the display apparatus 100 shown in FIG. 1A), a host processor 122, environmental sensors 124, a user input module 126, and a power source.

The display apparatus 128 includes a plurality of scan drivers 130 (also referred to as write enabling voltage sources), a plurality of data drivers 132 (also referred to as data voltage sources), a controller 134, common drivers 138, lamps 140-146, lamp drivers 148 and an array of display elements 150, such as the light modulators 102 shown in FIG. 1A. The scan drivers 130 apply write enabling voltages to scan line interconnects 131. The data drivers 132 apply data voltages to the data interconnects 133.

In some implementations of the display apparatus, the data drivers 132 are capable of providing analog data voltages to the array of display elements 150, especially where the luminance level of the image is to be derived in analog fashion. In analog operation, the display elements are designed such that when a range of intermediate voltages is applied through the data interconnects 133, there results a range of intermediate illumination states or luminance levels in the resulting image. In some other implementations, the data drivers 132 are capable of applying a reduced set, such as 2, 3 or 4, of digital voltage levels to the data interconnects 133. In implementations in which the display elements are shutter-based light modulators, such as the light modulators 102 shown in FIG. 1A, these voltage levels are designed to set, in digital fashion, an open state, a closed state, or other discrete state to each of the shutters 108. In some implementations, the drivers are capable of switching between analog and digital modes.

The scan drivers 130 and the data drivers 132 are connected to a digital controller circuit 134 (also referred to as the controller 134). The controller 134 sends data to the data drivers 132 in a mostly serial fashion, organized in sequences, which in some implementations may be predetermined, grouped by rows and by image frames. The data drivers 132 can include series-to-parallel data converters, level-shifting, and for some applications digital-to-analog voltage converters.

The display apparatus optionally includes a set of common drivers 138, also referred to as common voltage sources. In some implementations, the common drivers 138 provide a DC common potential to all display elements within the array 150 of display elements, for instance by supplying voltage to a series of common interconnects 139. In some other implementations, the common drivers 138, following commands from the controller 134, issue voltage pulses or signals to the array of display elements 150, for instance global actuation pulses which are capable of driving and/or initiating simultaneous actuation of all display elements in multiple rows and columns of the array.

Each of the drivers (such as scan drivers 130, data drivers 132 and common drivers 138) for different display functions can be time-synchronized by the controller 134. Timing commands from the controller 134 coordinate the illumination of red, green, blue and white lamps (140, 142, 144 and 146 respectively) via lamp drivers 148, the write-enabling and sequencing of specific rows within the array of display elements 150, the output of voltages from the data drivers 132, and the output of voltages that provide for display element actuation. In some implementations, the lamps are light emitting diodes (LEDs).

The controller 134 determines the sequencing or addressing scheme by which each of the display elements can be re-set to the illumination levels appropriate to a new image 104. New images 104 can be set at periodic intervals. For instance, for video displays, color images or frames of video are refreshed at frequencies ranging from 10 to 300 Hertz (Hz). In some implementations, the setting of an image frame to the array of display elements 150 is synchronized with the illumination of the lamps 140, 142, 144 and 146 such that alternate image frames are illuminated with an alternating series of colors, such as red, green, blue and white. The image frames for each respective color are referred to as color subframes. In this method, referred to as the field sequential color method, if the color subframes are alternated at frequencies in excess of 20 Hz, the human visual system (HVS) will average the alternating frame images into the perception of an image having a broad and continuous range of colors. In some other implementations, the lamps can employ primary colors other than red, green, blue and white. In some implementations, fewer than four, or more than four lamps with primary colors can be employed in the display apparatus 128.

In some implementations, where the display apparatus 128 is designed for the digital switching of shutters, such as the shutters 108 shown in FIG. 1A, between open and closed states, the controller 134 forms an image by the method of time division gray scale. In some other implementations, the display apparatus 128 can provide gray scale through the use of multiple display elements per pixel.

In some implementations, the data for an image state is loaded by the controller 134 to the array of display elements 150 by a sequential addressing of individual rows, also referred to as scan lines. For each row or scan line in the sequence, the scan driver 130 applies a write-enable voltage to the write enable interconnect 131 for that row of the array of display elements 150, and subsequently the data driver 132 supplies data voltages, corresponding to desired shutter states, for each column in the selected row of the array. This addressing process can repeat until data has been loaded for all rows in the array of display elements 150. In some implementations, the sequence of selected rows for data loading is linear, proceeding from top to bottom in the array of display elements 150. In some other implementations, the sequence of selected rows is pseudo-randomized, in order to mitigate potential visual artifacts. And in some other implementations, the sequencing is organized by blocks, where, for a block, the data for a certain fraction of the image is loaded to the array of display elements 150. For example, the sequence can be implemented to address every fifth row of the array of the display elements 150 in sequence.

In some implementations, the addressing process for loading image data to the array of display elements 150 is separated in time from the process of actuating the display elements. In such an implementation, the array of display elements 150 may include data memory elements for each display element, and the control matrix may include a global actuation interconnect for carrying trigger signals, from the common driver 138, to initiate simultaneous actuation of the display elements according to data stored in the memory elements.

In some implementations, the array of display elements 150 and the control matrix that controls the display elements may be arranged in configurations other than rectangular rows and columns. For example, the display elements can be arranged in hexagonal arrays or curvilinear rows and columns.

The host processor 122 generally controls the operations of the host device 120. For example, the host processor 122 may be a general or special purpose processor for controlling a portable electronic device. With respect to the display apparatus 128, included within the host device 120, the host processor 122 outputs image data as well as additional data about the host device 120. Such information may include data from environmental sensors 124, such as ambient light or temperature; information about the host device 120, including, for example, an operating mode of the host or the amount of power remaining in the host device's power source; information about the content of the image data; information about the type of image data; and/or instructions for the display apparatus 128 for use in selecting an imaging mode.

In some implementations, the user input module 126 enables the conveyance of personal preferences of a user to the controller 134, either directly, or via the host processor 122. In some implementations, the user input module 126 is controlled by software in which a user inputs personal preferences, for example, color, contrast, power, brightness, content, and other display settings and parameters preferences. In some other implementations, the user input module 126 is controlled by hardware in which a user inputs personal preferences. In some implementations, the user may input these preferences via voice commands, one or more buttons, switches or dials, or with touch-capability. The plurality of data inputs to the controller 134 direct the controller to provide data to the various drivers 130, 132, 138 and 148 which correspond to optimal imaging characteristics.

The environmental sensor module 124 also can be included as part of the host device 120. The environmental sensor module 124 can be capable of receiving data about the ambient environment, such as temperature and or ambient lighting conditions. The sensor module 124 can be programmed, for example, to distinguish whether the device is operating in an indoor or office environment versus an outdoor environment in bright daylight versus an outdoor environment at nighttime. The sensor module 124 communicates this information to the display controller 134, so that the controller 134 can optimize the viewing conditions in response to the ambient environment.

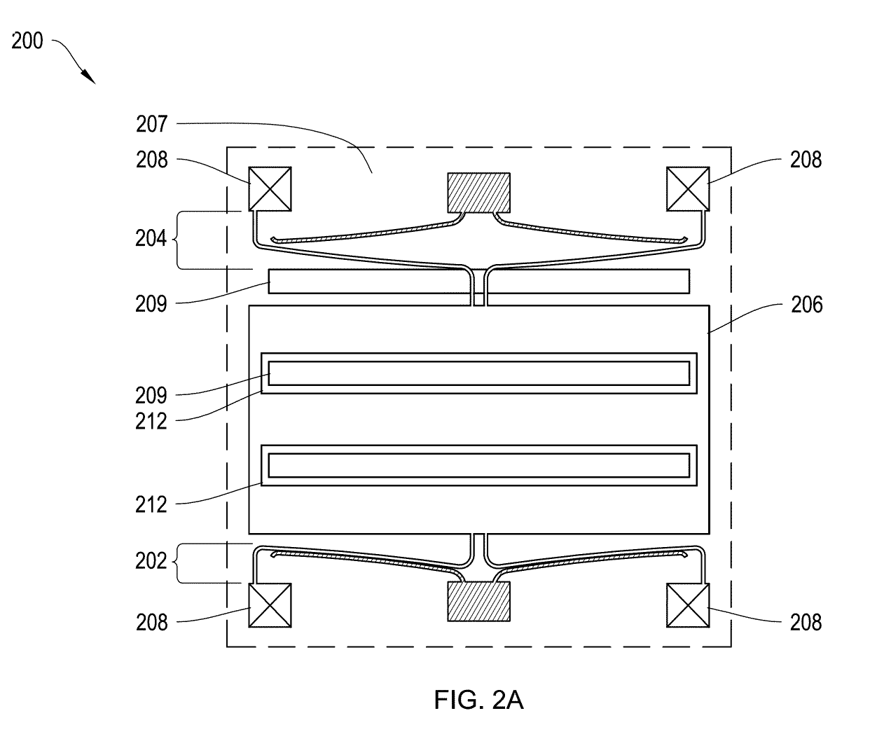

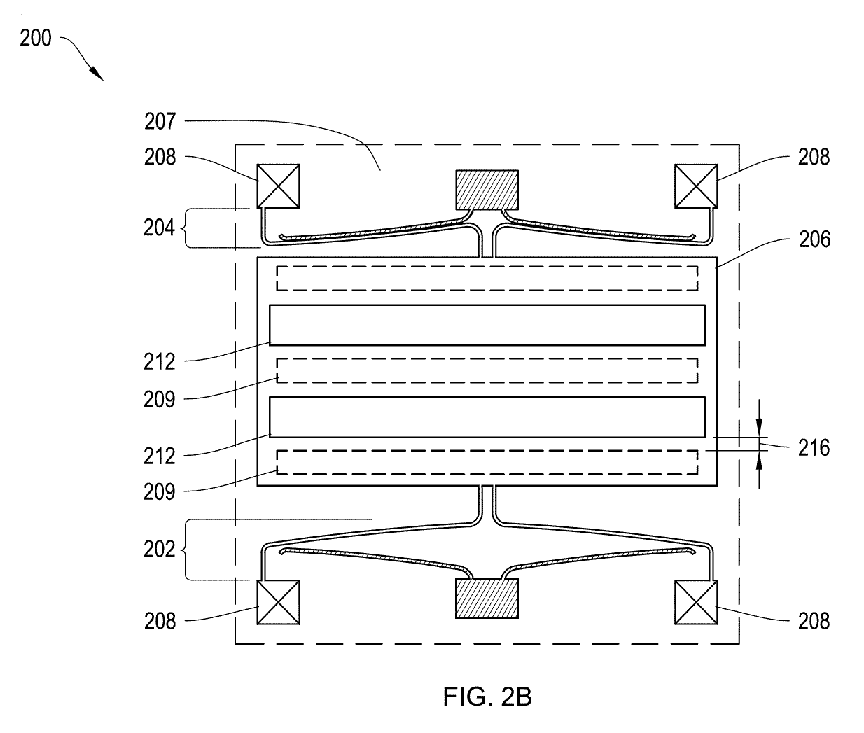

FIGS. 2A and 2B show views of an example dual actuator shutter assembly 200. The dual actuator shutter assembly 200, as depicted in FIG. 2A, is in an open state. FIG. 2B shows the dual actuator shutter assembly 200 in a closed state. The shutter assembly 200 includes actuators 202 and 204 on either side of a shutter 206. Each actuator 202 and 204 is independently controlled. A first actuator, a shutter-open actuator 202, serves to open the shutter 206. A second opposing actuator, the shutter-close actuator 204, serves to close the shutter 206. Each of the actuators 202 and 204 can be implemented as compliant beam electrode actuators. The actuators 202 and 204 open and close the shutter 206 by driving the shutter 206 substantially in a plane parallel to an aperture layer 207 over which the shutter is suspended. The shutter 206 is suspended a short distance over the aperture layer 207 by anchors 208 attached to the actuators 202 and 204. Having the actuators 202 and 204 attach to opposing ends of the shutter 206 along its axis of movement reduces out of plane motion of the shutter 206 and confines the motion substantially to a plane parallel to the substrate (not depicted).

In the depicted implementation, the shutter 206 includes two shutter apertures 212 through which light can pass. The aperture layer 207 includes a set of three apertures 209. In FIG. 2A, the shutter assembly 200 is in the open state and, as such, the shutter-open actuator 202 has been actuated, the shutter-close actuator 204 is in its relaxed position, and the centerlines of the shutter apertures 212 coincide with the centerlines of two of the aperture layer apertures 209. In FIG. 2B, the shutter assembly 200 has been moved to the closed state and, as such, the shutter-open actuator 202 is in its relaxed position, the shutter-close actuator 204 has been actuated, and the light blocking portions of the shutter 206 are now in position to block transmission of light through the apertures 209 (depicted as dotted lines).

Each aperture has at least one edge around its periphery. For example, the rectangular apertures 209 have four edges. In some implementations, in which circular, elliptical, oval, or other curved apertures are formed in the aperture layer 207, each aperture may have a single edge. In some other implementations, the apertures need not be separated or disjointed in the mathematical sense, but instead can be connected. That is to say, while portions or shaped sections of the aperture may maintain a correspondence to each shutter, several of these sections may be connected such that a single continuous perimeter of the aperture is shared by multiple shutters.

In order to allow light with a variety of exit angles to pass through the apertures 212 and 209 in the open state, the width or size of the shutter apertures 212 can be designed to be larger than a corresponding width or size of apertures 209 in the aperture layer 207. In order to effectively block light from escaping in the closed state, the light blocking portions of the shutter 206 can be designed to overlap the edges of the apertures 209. FIG. 2B shows an overlap 216, which in some implementations can be predefined, between the edge of light blocking portions in the shutter 206 and one edge of the aperture 209 formed in the aperture layer 207.

The electrostatic actuators 202 and 204 are designed so that their voltage-displacement behavior provides a bi-stable characteristic to the shutter assembly 200. For each of the shutter-open and shutter-close actuators, there exists a range of voltages below the actuation voltage, which if applied while that actuator is in the closed state (with the shutter being either open or closed), will hold the actuator closed and the shutter in position, even after a drive voltage is applied to the opposing actuator. The minimum voltage needed to maintain a shutter's position against such an opposing force is referred to as a maintenance voltage Vₘ.

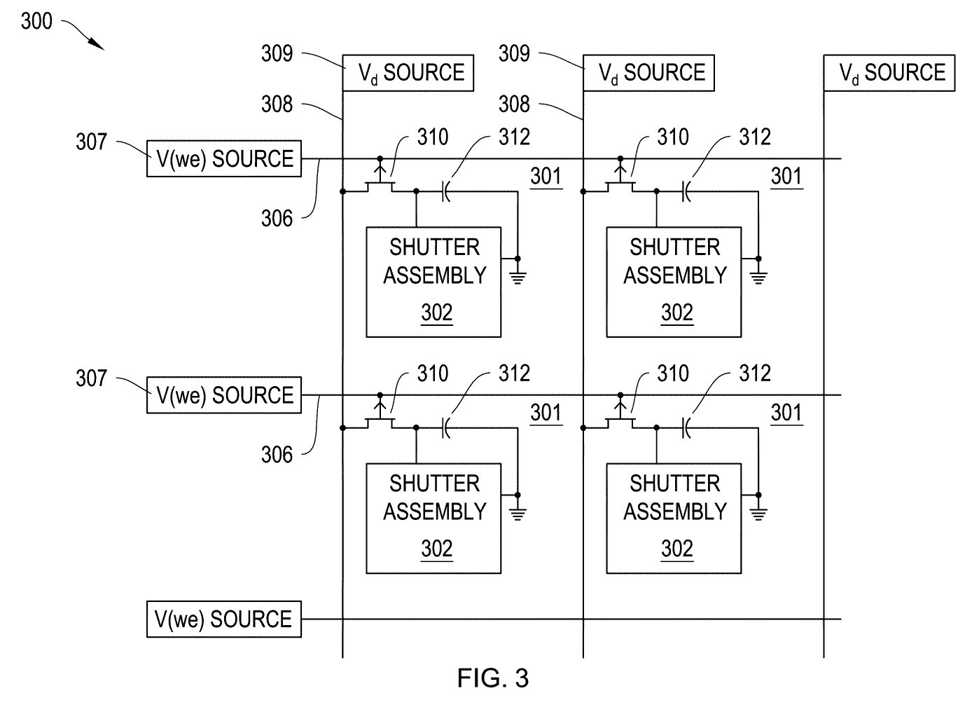

FIG. 3 shows a schematic diagram of an example control matrix 300 suitable for controlling the light modulators of the display apparatus of FIGS. 1 and 2. The control matrix 300 may include control circuitry for controlling operation of a pixel in an array of pixels associated with the array of shutter assemblies 302. In the example shown in FIG. 3, each pixel 301 includes a shutter assembly 302, such as the shutter assembly 200 of FIG. 2. In some implementations, each pixel 301 may include a single actuator shutter, a dual-actuator shutter assembly, or another type of light modulator.

The control matrix 300, including control circuitry, may be fabricated as a diffused or thin-film-deposited electrical circuit on the surface of a substrate on which the shutter assemblies 302 are formed. The control circuitry of control matrix 300 may include a row interconnect 306 (also known as a “write-enabling” interconnect) for each row of pixels 301 in the control matrix 300 and a column interconnect 308 (also known as a “data” interconnect) for each column of pixels 301 in the control matrix 300. Each row interconnect 306 electrically connects a row driver 307 (also known as a “write-enabling voltage source”) for providing a voltage, V_{(we)}, to the pixels 301 in a corresponding row of pixels 301. The row interconnects 306 may be electrically connected to the row driver 307 by a routing interconnect (not shown), or the row interconnects 306 may directly connect to the row driver 307. Each column interconnect 308 electrically connects a column driver 309 (also known as a “data voltage source”) for providing a voltage, V_{d}, to the pixels 301 in a corresponding column of pixels 301. The column interconnects 308 may be electrically connected to the column driver 309 by a routing interconnect (not shown), or the column interconnect 308 may directly connect to the column driver 309. In implementations using dual-actuated shutter assemblies, the control matrix 300 may include two column interconnects for each pixel 301 for controlling the dual-actuated shutter assemblies 302. In the control matrix 300, the data voltage V_{d} provides the majority of the energy for actuation of the shutter assemblies 302. Thus, the column driver 309 also serves as an actuation voltage source. In some implementations, an actuation voltage source may provide the majority of energy for actuation of the shutter assemblies 300.

Referring to FIG. 3, for each pixel 301 or for each shutter assembly 302 in the array of pixels 320, the control matrix 300 includes a transistor 310 and a capacitor 312. The gate of each transistor 310 is electrically connected to the row interconnect 306 of the row in the array 320 in which the pixel 301 is located. The source of each transistor 310 is electrically connected to its corresponding column interconnect 308. The actuators of each shutter assembly 302 include two electrodes. The drain of each transistor 310 is electrically connected in parallel to one electrode of the corresponding capacitor 312 and to one of the electrodes of the corresponding actuator 303. The other electrode of the capacitor 312 and the other electrode of the actuator 303 in shutter assembly 302 are connected to a common or ground potential. In alternate implementations, the transistors 310 can be replaced with semiconductor diodes and or metal-insulator-metal sandwich type switching elements.

In operation, to form an image, the control matrix 300 write-enables each row in the array 320 in a sequence by applying V_{we} to each row interconnect 306 in turn. For a write-enabled row, the application of V_{we} to the gates of the transistors 310 of the pixels 301 in the row allows the flow of current through the column interconnects 308 through the transistors 310 to apply a potential to the actuator 303 of the shutter assembly 302. While the row is write-enabled, data voltages V_{d} are selectively applied to the column interconnects 308. In implementations providing analog grayscale, the data voltage applied to each column interconnect 308 is varied in relation to the desired brightness of the pixel 301 located at the intersection of the write-enabled row interconnect 306 and the column interconnect 308. In implementations providing digital control schemes, the data voltage is selected to be either a relatively low magnitude voltage (i.e., a voltage near ground) or to meet or exceed Vₐₜ (the actuation threshold voltage). In response to the application of Vₐₜ to a column interconnect 308, the actuator 303 in the corresponding shutter assembly 302 actuates, opening the shutter in that shutter assembly 302. The voltage applied to the column interconnect 308 remains stored in the capacitor 312 of the pixel 301 even after the control matrix 300 ceases to apply V_{we} to a row. It is not needed, therefore, to wait and hold the voltage V_{we} on a row for times long enough for the shutter assembly 302 to actuate; such actuation can proceed after the write-enabling voltage has been removed from the row. The capacitors 312 also function as memory elements within the array 320, storing actuation instructions for periods as long as is needed for the illumination of an image frame.

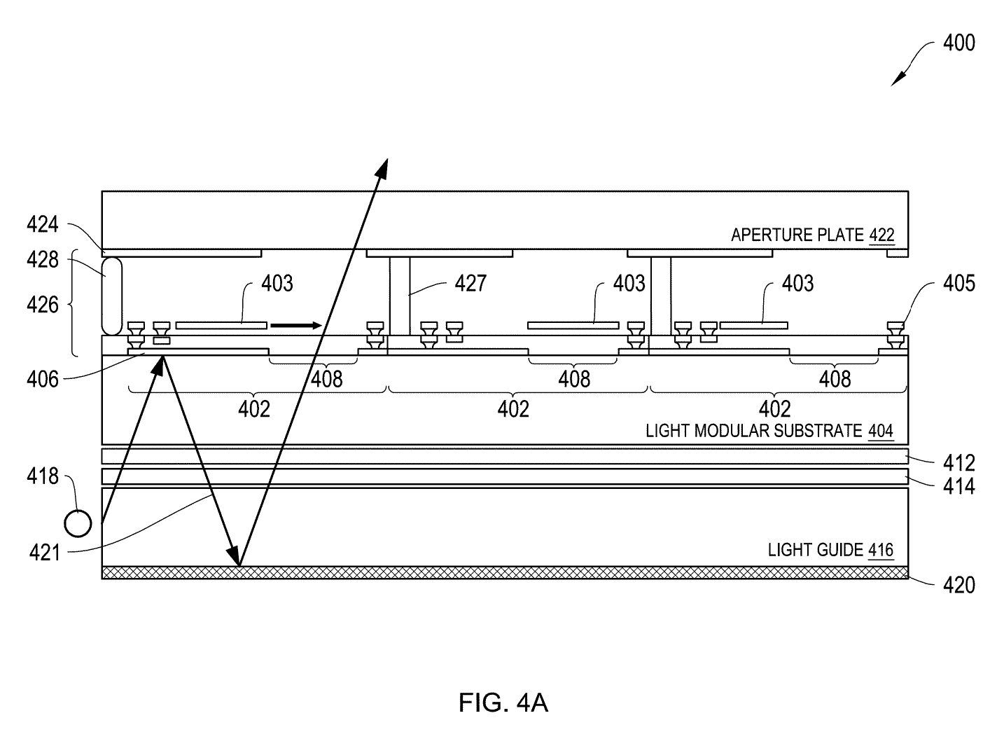

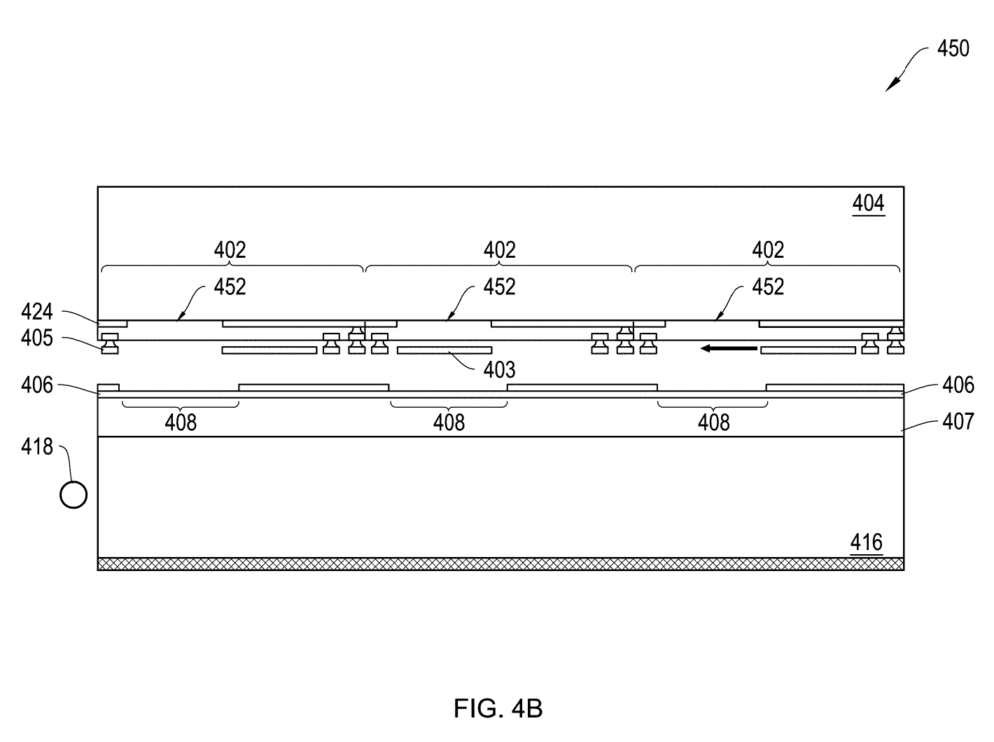

FIG. 4A shows a cross sectional view of an example MEMS-up implementation of a display apparatus 400 incorporating shutter-based light modulators (shutter assemblies) 402. Each shutter assembly 402 incorporates a shutter 403 and an anchor 405. Not shown are the compliant beam actuators which, when connected between the anchors 405 and the shutters 403, help to suspend the shutters a short distance above the surface. The shutter assemblies 402 are disposed on a transparent substrate 404 that may be made of plastic, glass or another transparent material. A rear-facing reflective layer, the reflective film 406, disposed on the substrate 404 defines a plurality of surface apertures 408 located beneath the closed positions of the shutters 403 of the shutter assemblies 402. The reflective film 406 reflects light not passing through the surface apertures 408 back towards the rear of the display apparatus 400. The reflective aperture layer 406 can be a fine-grained metal film without inclusions formed in thin film fashion by a number of deposition techniques including sputtering, evaporation, ion plating, laser ablation, or chemical vapor deposition. In another implementation, the rear-facing reflective layer 406 can be formed from a mirror, such as a dielectric mirror. A dielectric mirror is fabricated as a stack of dielectric thin films which alternate between materials of high and low refractive index. The vertical gap which separates the shutters 403 from the reflective film 406, within which the shutter is free to move, may be in the range of 0.5 to 10 microns. The magnitude of the vertical gap may be less than the lateral overlap between the edge of the shutters 403 and the edge of the apertures 408 in the closed state. In some implementations, the vertical gap may be smaller than the horizontal overlap thereby reducing light leakage.

The display apparatus 400 includes an optional diffuser 412 and/or an optional brightness enhancing film 414 which separate the substrate 404 from a planar light guide 416. The light guide 416 includes a transparent (i.e., glass or plastic) material. The depicted light guide 416 is illuminated by one or more light sources 418, forming a backlight. The light sources 418 can be, for example, and without limitation, incandescent lamps, fluorescent lamps, lasers, light emitting diodes (LEDs), or Quantum Dots (QD). A front-facing reflective film 420 is disposed behind the backlight 416, reflecting light towards the shutter assemblies 402. Light rays such as ray 421 from the backlight that do not pass through one of the shutter assemblies 402 will be returned to the backlight and reflected again from the reflective film 420. In this fashion light that fails to leave the display to form an image on the first pass can be recycled and made available for transmission through other open apertures in the array of shutter assemblies 402. Such light recycling has been shown to increase the illumination efficiency of the display.

In alternate implementations, the aperture layer 406 can be made of a light absorbing material, and in alternate implementations the surfaces of shutter 403 can be coated with either a light absorbing or a light reflecting material. In alternate implementations the aperture layer 406 can be deposited directly on the surface of the light guide 416. In alternate implementations, the aperture layer 406 need not be disposed on the same substrate as the shutters 403 and the anchors 405.

An aperture plate 422 forms the front of the display apparatus 400. The rear side of the aperture plate 422 can be covered with a black matrix 424 to increase contrast. In alternate implementations, the aperture plate 422 includes color filters, for instance distinct red, green, and blue filters corresponding to different ones of the shutter assemblies 402. The aperture plate 422, in some implementations, is supported a predetermined distance away from the shutter assemblies 402 forming the depicted gap 426. The gap 426 is maintained by spacers 427 and/or by an adhesive seal 428 attaching the aperture plate 422 to the substrate 404. The adhesive seal 428 may seal in a working fluid. The working fluid also can serve as a lubricant. In some implementations, the working fluid is a hydrophobic liquid with a low surface wetting capability. In some implementations, the working fluid may have a good surface wetting capability and may not mix well with water. While the surfaces may be hydrophobic, they may also be oleophilic. Not shown in FIG. 4A are electrical interconnects which provide control signals as well as power to the shutter assemblies 402 and the lamps 418.

The display apparatus 400 of FIG. 4A is referred to as the MEMS-up configuration, where the MEMS based light modulators are formed on a front surface of substrate 404, i.e. the surface that faces toward the viewer. The shutter assemblies 402 are built directly on top of the reflective aperture layer 406. In an alternate implementation, referred to as the MEMS-down configuration, the shutter assemblies 402 are disposed on a substrate separate from the substrate on which the reflective aperture layer 406 is formed.

FIG. 4B shows a cross-sectional view of an example MEMS-down implementation of a shutter-based display apparatus 450. In the MEMS-down configuration of FIG. 4B, the substrate 404 that carries the MEMS-based light modulators 402 takes the place of the aperture plate 422 in display apparatus 400 of FIG. 4A and is oriented such that the MEMS-based light modulators 402 are positioned on the rear surface of the top substrate, i.e., the surface that faces away from the viewer and toward the light guide 416. In the MEMS-down implementation, the MEMS-based light modulators 402 are positioned directly opposite to and across a gap from the reflective aperture layer 406. The gap can be maintained by a series of spacers (not shown) connecting the aperture plate 407 and the substrate 404 on which the MEMS modulators 402 are formed. In some implementations, the spacers are disposed within or between each pixel in the array. The gap or distance that separates the MEMS light modulators 402 from their corresponding apertures 408 may be less than 10 microns, or a distance that is less than the overlap between shutters and apertures. The shutter assemblies 402 formed on the substrate 404 are aligned with the respective apertures 408 formed, in this implementation, within a reflecting film that forms the aperture layer 406 on the aperture plate 407. Light from the light guide 416 may pass through the apertures 408 within the aperture layer 406, and pass toward the apertures 452 formed within a layer 424. In one implementation, the layer 424 is a layer of metal material deposited on the surface of a transparent substrate 404 that in one implementation is formed of glass, plastic or some other suitable material. The shutter 403 of a shutter assembly 402 may move to a position between the apertures 408 and 452 to block light from passing through the aperture 408 and into the aperture 452. Alternatively, the shutter 403 may be positioned laterally away from the apertures 408 and 452, to allow light to pass from the aperture 408 and through the aperture 452.

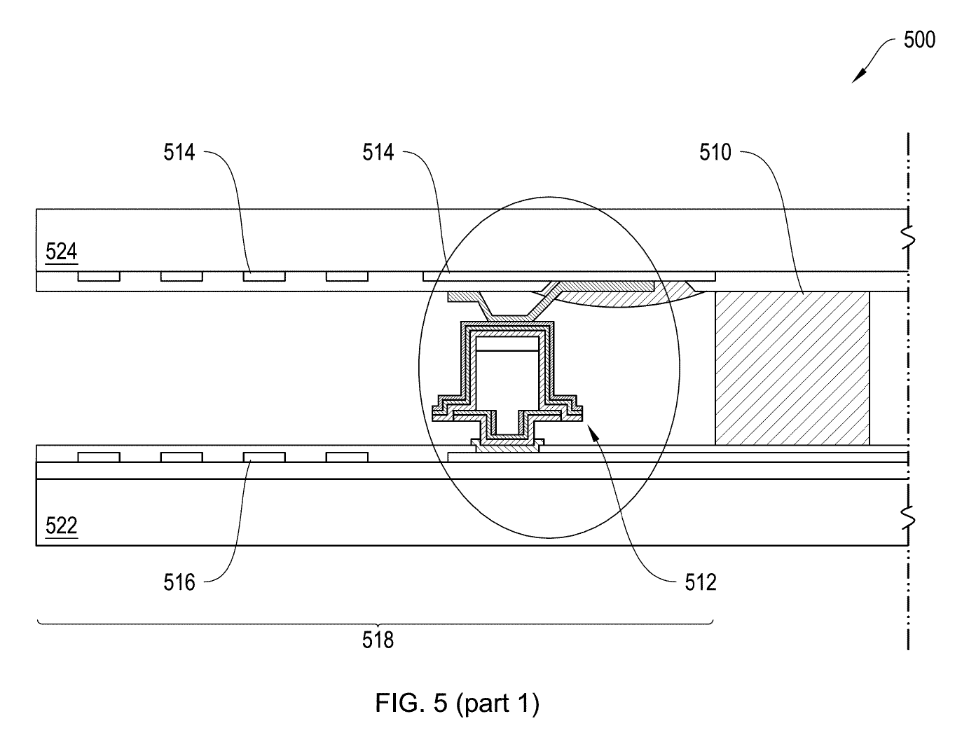

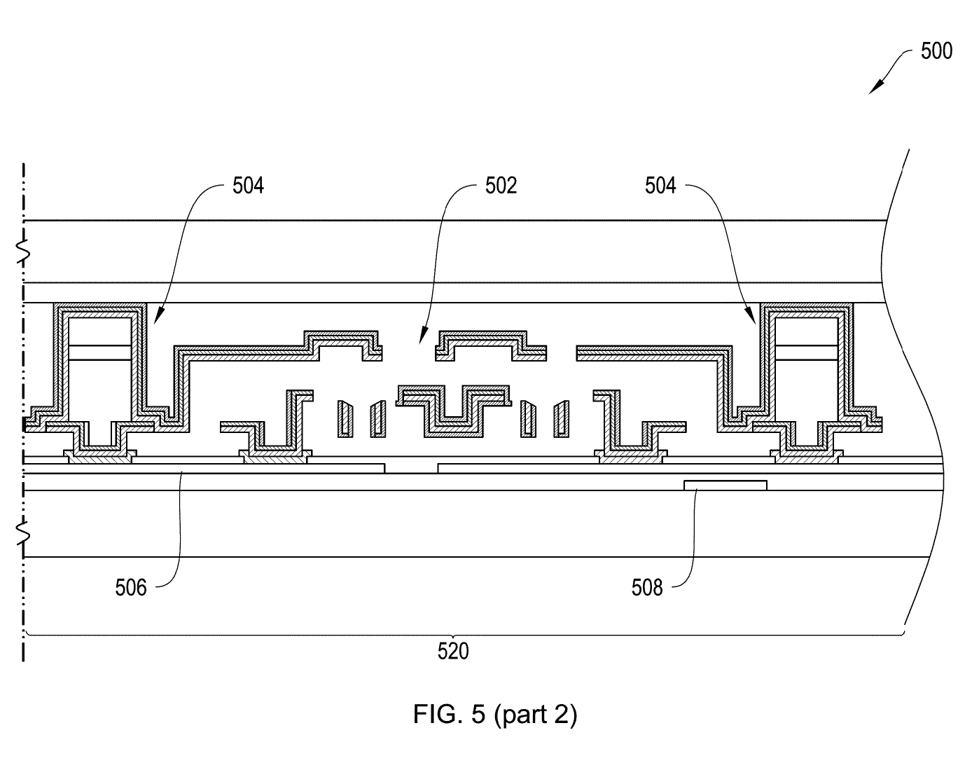

FIG. 5 shows a cross-sectional view of an example display apparatus 500 illustrating routing interconnects on the substrate and the aperture plate. Depending on the location of the backlight, the display apparatus 500 may be of the MEMS-up configuration of FIG. 4A or the MEMS-down configuration of FIG. 4B. For example, if a backlight and light guide are located below the substrate 522, the display apparatus 500 would be in a MEMS-up configuration with a viewer viewing from above the display apparatus 500. In contrast, if the backlight and light guide are located above the aperture plate 524, the display apparatus 500 would be in a MEMS-down configuration with a viewer viewing a displayed image from below the display apparatus 500.

The Display apparatus 500 includes MEMS light modulators 502 formed on the substrate 522. Row interconnects 506 and column interconnects 508 are also formed on the substrate 522. The row interconnects 506 and column interconnects 508 may be formed from metal or another suitable conductor for carrying an electrical signal. The row interconnects 506 and column interconnects 508 are coupled to the MEMS light modulator 502 and control actuation of the MEMS light modulator 502 as described with respect to FIGS. 1-3. The display apparatus 500 includes a display area 520 and a bezel area 518. The display area 520 includes an array of pixels, including a plurality of light modulators 502, for forming an image to be viewed by a viewer. The bezel area 518 of the display apparatus 500 does not form part of the image to be viewed by a viewer. Spacers 504 separate the substrate 522 from the aperture plate 524 creating a gap in which the MEMS light modulators 502 are located. Seal 510 also separates the substrate 522 from the aperture plate 524 and separates the display area 520 from the bezel area 518.

The bezel area 518 includes routing interconnects 514 formed on the aperture plate 524, and routing interconnects 516 formed on the substrate 522. The bezel area 518 also includes an electrically conductive spacer 512 which electrically couples a row interconnect 506 to one or more of a plurality of routing interconnects 514. In some implementations, each pixel in the array of pixels includes at least one row interconnect 506, at least one column interconnect 508 and at least one routing interconnect 514. For example, FIG. 5 illustrates just one pixel in a display area 520 corresponding to a row interconnect 506 and a column interconnect 508. The row interconnect 506 makes electrical contact with a single routing interconnect 514 via a conductive spacer 512. However, multiple pixels may be included in the array of pixels corresponding to the intersection of one or more column interconnects and one or more row interconnects. Other pixels in the array of pixels may be connected to separate routing interconnects on the aperture plate 524 (such as routing interconnects 514), or on the substrate (such as routing interconnects 516).

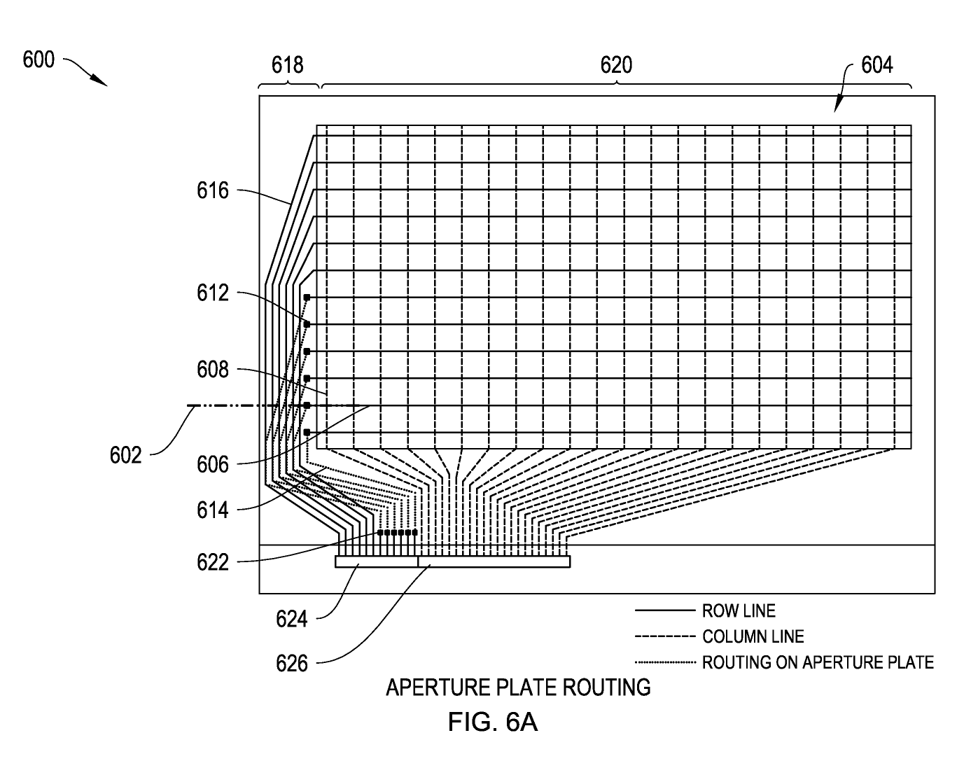

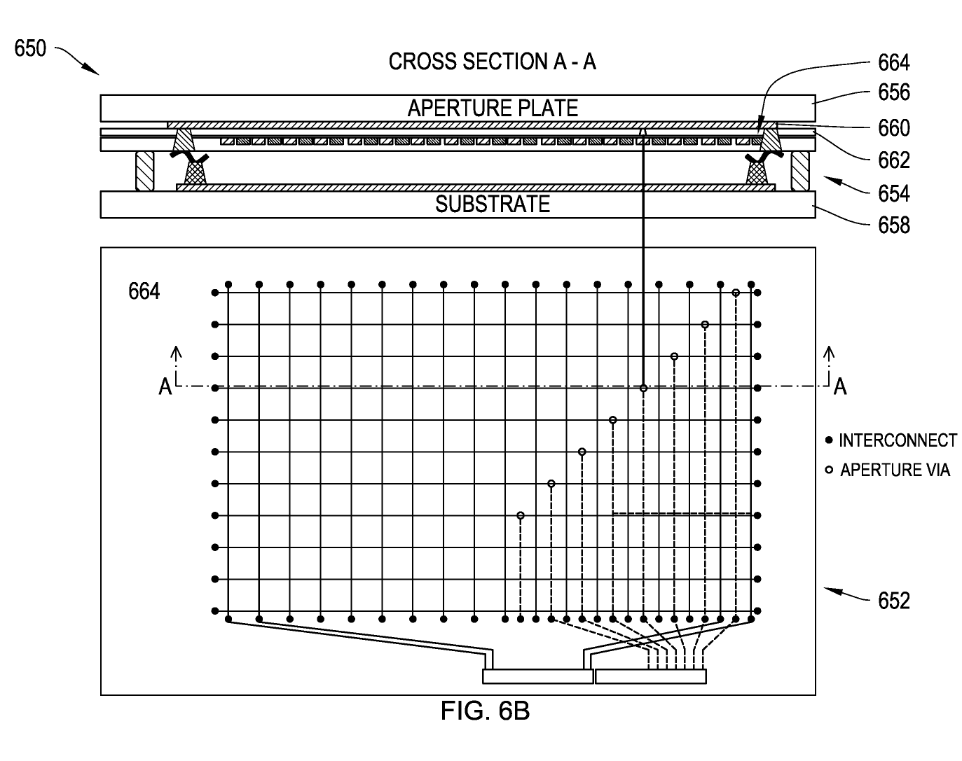

FIG. 6A shows a plan view of an example display apparatus 600 illustrating row, column and routing interconnects for an array of pixels. The display apparatus 600 includes an array of pixels 604 located within a display area 620 and a bezel area 618 including routing interconnects 616 and routing interconnects 614. The display apparatus 600 corresponds to the cross-sectional view of the display apparatus 500, from the perspective of cross-section line 602. The display apparatus 500 corresponds to the cross-section of the bezel area and a single pixel out of the array of pixels 604. As described with respect to FIG. 5, the routing interconnects 616 are formed on the substrate, while the routing interconnects 614 are formed on the aperture plate. Each pixel in display area 620 includes a row interconnect 606 and a column interconnect 608. A portion of the row interconnects 606 electrically connect to the routing interconnects 612 via an electrically conductive spacer and a contact pad (as described with respect to FIG. 5 above) within the bezel area 618. A separate portion of the row interconnects 606 are directly connected to the routing interconnects 616 in the bezel area 618.

Both routing interconnects 614 and 616 electrically connect to a row driver 624. The routing interconnects 614, fabricated on the aperture plate, may electrically connect to the row driver interconnects via at least one conductive spacer 622. The row driver 624 may be fabricated on the substrate. The column interconnects 608 electrically connect to a column driver 626. The column driver 626 may be fabricated on the substrate. As shown in FIG. 6, the row driver 624 and the column driver 626 are located outside of the display area 620 and on one side of the display area 620. However, the row driver 624 and the column driver 626 may be located anywhere outside of the display area 620 (i.e., above, below, to the left or to the right), or may be located in a combination of positions outside of the display area 620. In some implementations, the row driver 624 and the column driver 626 may be fabricated on the aperture plate. In some implementations, the row driver 624 and the column driver 626 may be located on a flexible printed circuit (FPC). If through-glass vias are implemented then the row driver 624 and the column driver 626 may be located on the back side of either the a backplane or the aperture plate. In some implementations, the row driver 624 and the column driver 626 are implemented with TFTs, and may be located on the backplane. Routing interconnects may be fabricated using a dark metal as part of an aperture plate masking process.

FIG. 6B shows an example display apparatus 650. FIG. 6B includes a plan view 652 of the display apparatus 650 that is aligned with a corresponding cross-sectional view 654 of the display apparatus 650. The display apparatus 650 includes an aperture plate 656 suspended over a substrate 658. The aperture plate 656 includes a dark metal row routing layer 660, a dark metal column routing layer 664, and an insulator layer 662. Both column and row routing are possible on the aperture plate 656. With interconnects on both ends of the display apparatus 650, faster signal routing with minimal signal distortion and propagation delay can be accomplished. This configuration can be advantageous for larger display formats. Using the dark metal routing developed for high contrast ratio, the dual objectives of high contrast ratio and low resistance routing can be accomplished. In addition, having interconnects at both ends of the display apparatus 650 provides redundancy while keeping bezel area 664 to a minimum. Accessing the column routing in the aperture plate 656 while also having row routing can be accomplished by routing lines parallel to the row routing and using vias to connect to the column routing. There is sufficient space on the aperture plate 656 to accommodate both column supply and row routing in alternate routing lines. Rows and columns may also be routed parallel in the aperture plate 656 and substrate 658 to lower routing resistance. Routing interconnects may be included as part of a black matrix, insulator polymer, or a dark conductor.

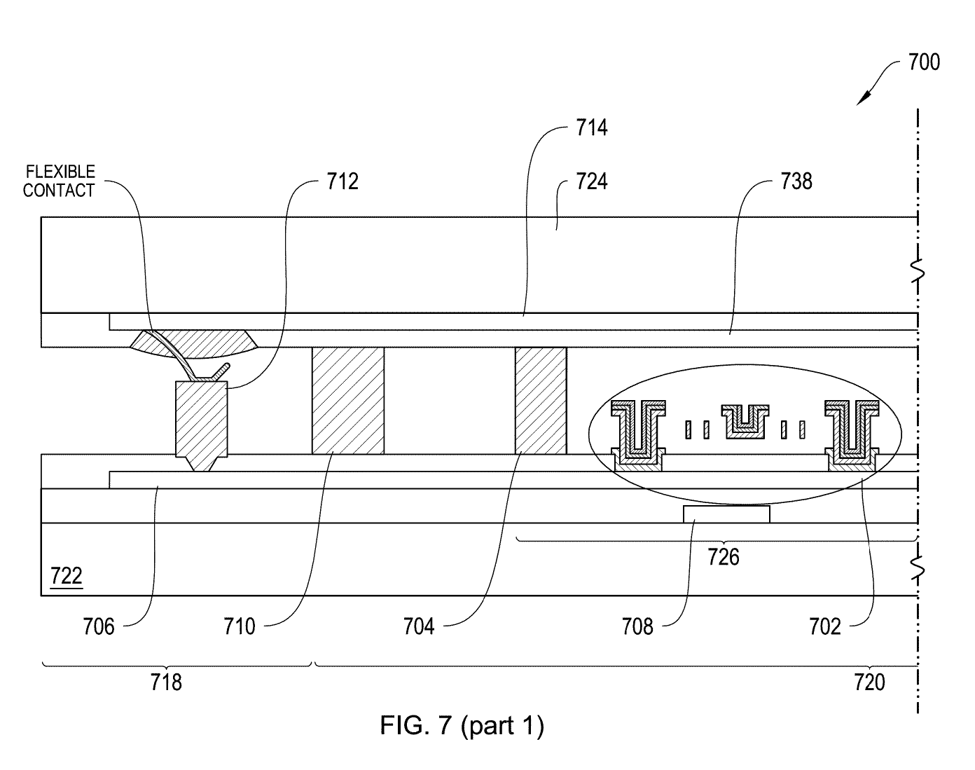

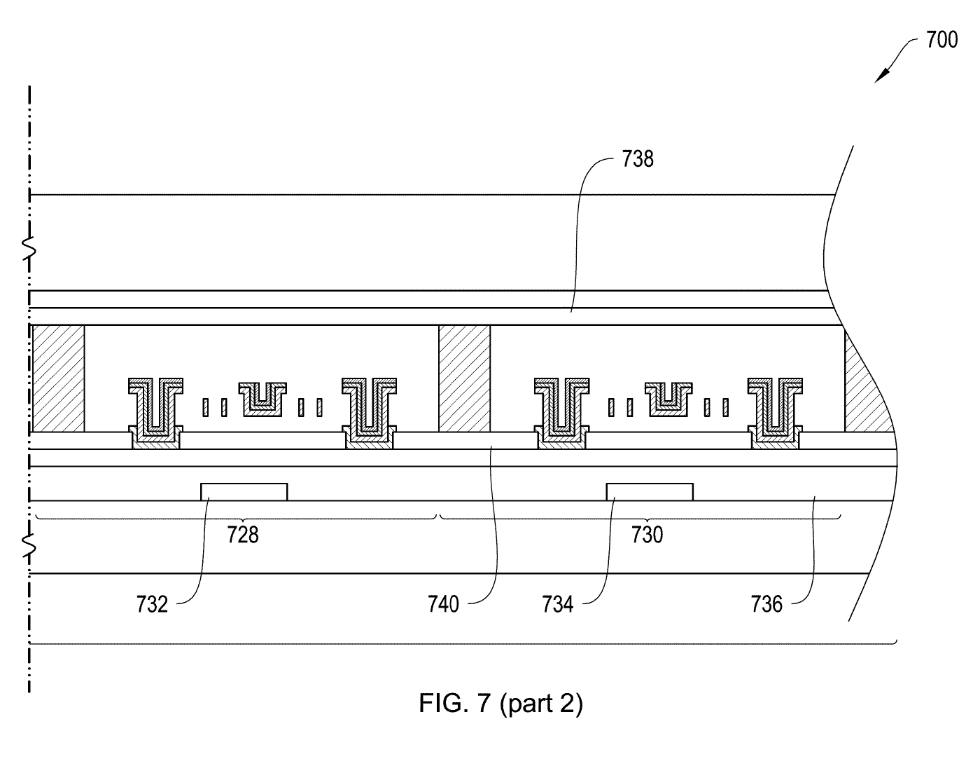

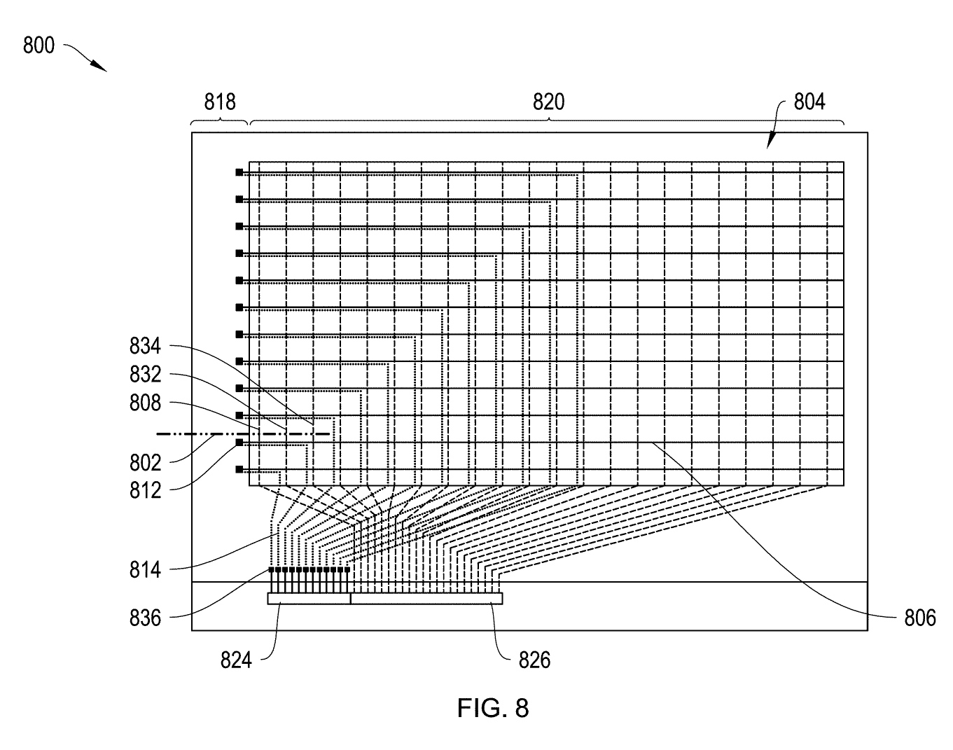

FIG. 7 shows a cross-sectional view of an example display apparatus 700 illustrating routing interconnects running through the display area. Display apparatus 700 includes display area 720 and bezel area 718 separated by seal 710. As shown in FIG. 7, the display area 720 includes three pixels 726, 728 and 730; however the display apparatus 700 may include more pixels in an array of pixels (not shown). Each pixel 726, 728 and 730 includes at least one MEMS light modulator 702. In some implementations, the MEMS light modulators 702 may include a shutter that moves transverse to the substrate 722. MEMS light modulators 702 are formed on the substrate 722. Spacers 704 separate the substrate 722 from the aperture plate 724 and create a gap for the MEMS light modulators 702. Also formed on the substrate 722 is the column interconnects 708, 732 and 734, first insulator 736, row interconnect 706 and second insulator 740. The first insulator 736 separates the conductive routing layers 706 (row) and 708, 732, 734 (column). The second insulator 740 protects the conductive layer 706 (row) and allows selective access to routing lines by etching via passages at selective location within a pixel. In some implementations, the first insulator 736 can function as an optical wave guide for a backlight, or a gate insulator for a TFT. Each pixel 726, 728 and 730 corresponds to at least one column interconnect and at least one row interconnect. The cross-sectional view of FIG. 7 is taken along a row in an array of pixels (see FIG. 8), and therefore each of pixels 726, 728 and 730 shares the same row interconnect 706. The row interconnect 706 electrically connects to a conductive spacer 712 on the substrate 722 in the bezel area 718. The conductive spacer 712 also electrically connects to a routing interconnect 714 on the aperture plate 724 in the bezel area 718. An insulating layer 738 is formed on the aperture plate between the routing interconnect 714 and the MEMS light modulators 702. In the display apparatus 700, the routing interconnect 714 runs through the display area 720 on the aperture plate 724. By running the routing interconnect 714 through the display area 720 instead of the bezel area 718, the size of bezel area 718 can be reduced. Also, by running the routing interconnect 714 through the display area 720, wider routing interconnects may be used and wider separation can be created between the routing interconnects. Wider routing interconnects and wider separation between routing interconnects can reduce line resistance thereby reducing signal delay in the display device. Furthermore, an opaque layer on the aperture plate 724 can embed conductive routing with minimal additional processing over the existing aperture plate. Therefore, the bezel area 718 can be reduced with minimal additional process steps. The routing interconnect 714 may electrically connect to a row driver (not shown).

FIG. 8 shows a plan view of an example display apparatus 800 illustrating row, column and routing interconnects. The display apparatus 800 includes a bezel area 818 and an array of pixels 804 located within a display area 820. The display apparatus 800 corresponds to the cross-sectional view of the display apparatus 700, from the perspective of cross-section line 802. The display apparatus 700 corresponds to the cross-section of the bezel area 818 and three pixels out of the array of pixels 804. As described with respect to FIG. 7, the routing interconnects 814 are formed on the aperture plate and run through the display area 820. The routing interconnect 714 of the display device 700 corresponds to one of the routing interconnects 814. In contrast with the display device 600 of FIG. 6, the routing interconnects 814 do not run through the bezel area 818. By running the routing interconnects 814 through the display area 820 the bezel area 818 can be reduced or eliminated.

Each pixel in the display area 820 includes a row interconnect 806 and a column interconnect 808, 832 and 834. The row interconnect 806 and column interconnects 808, 832 and 834 correspond to the row interconnect 706 and column interconnects 708, 732 and 734 of the display device 700. Each of the row interconnects 806 in the array 804 electrically connect to the routing interconnects 814 via an electrically conductive spacer and a contact pad 812 (as described with respect to FIG. 7 above) within the bezel area 818. The routing interconnects 814 electrically connect to a row driver 824. The routing interconnects 814, fabricated on the aperture plate, may electrically connect to row driver interconnects via a conductive spacer, such as the conductive spacer 812. For example, the routing interconnects 814 may electrically connect to the row driver interconnects at the contact pads 836 coupled to the conducive spacers (not shown). The row driver 824 may be fabricated on the substrate. Column interconnects 808, 832 and 834 electrically connect to a column driver 826. The column driver 826 may be fabricated on the substrate.

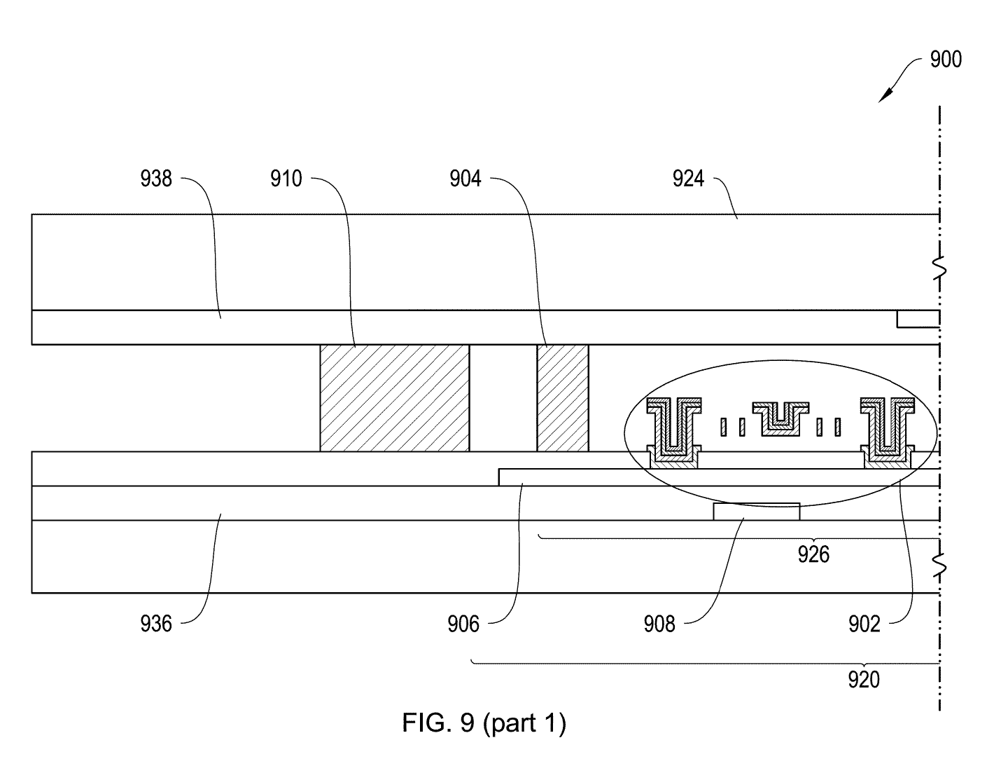

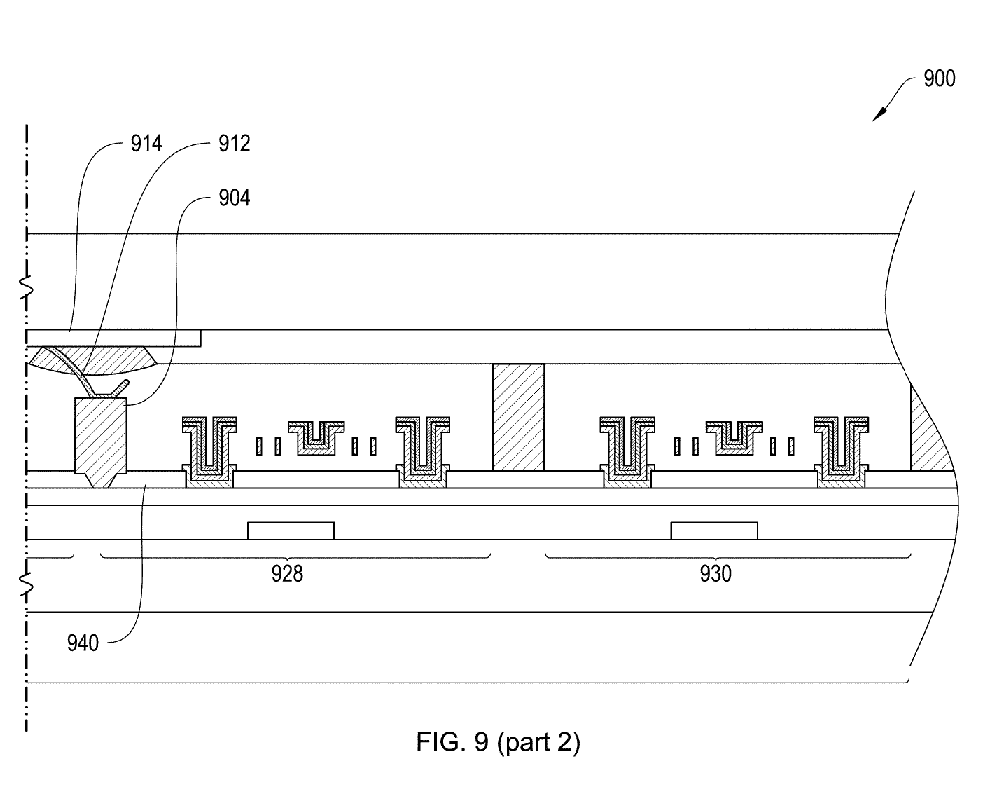

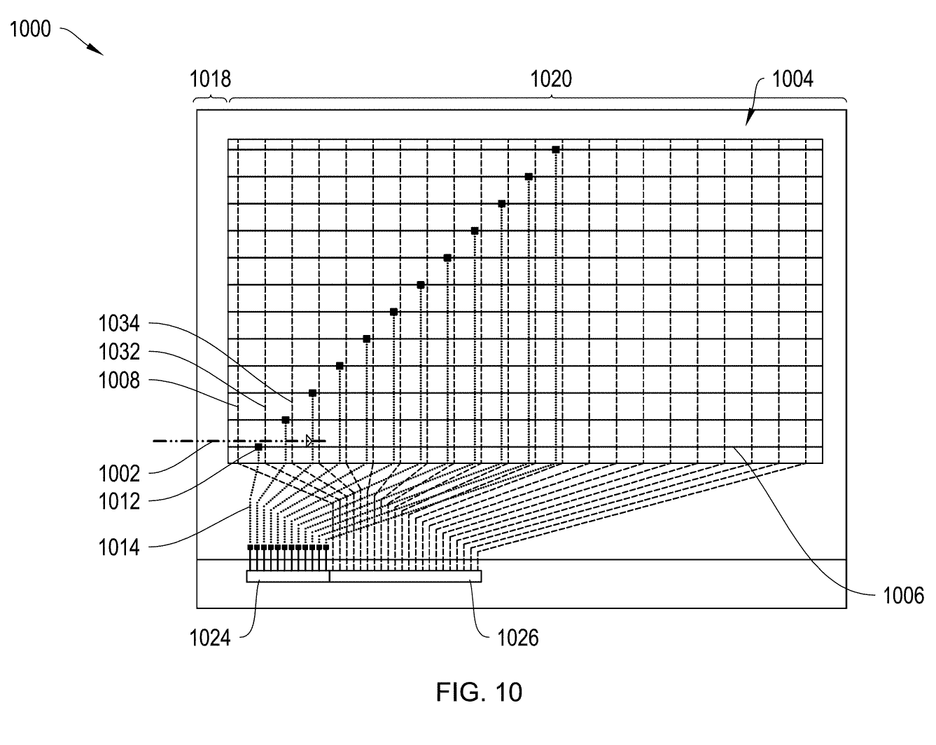

FIG. 9 shows a cross-sectional view of an example display apparatus 900 illustrating routing contacts in the display area. The display apparatus 900 includes a display area 920. As shown in FIG. 9, the display area 920 includes three pixels 926, 928 and 930; however the display apparatus 900 may include more than three pixels in an array of pixels (not shown). Each pixel 926, 928 and 930 includes at least one MEMS light modulator 902. The MEMS light modulators 902 are formed on the substrate 922. In some implementations, MEMS light modulators 902 may include a shutter that moves transverse to the substrate 922. Spacers 904 separate the substrate 922 from the aperture plate 924 and create a gap for the MEMS light modulators 902. Also formed on the substrate 922 are the column interconnects 908, 932 and 934, first insulator 936, row interconnect 906 and second insulator 940. The insulator layer 936 separates various conductive layers electrically and protects the conductive layers during the etching process. The first insulator layer 936 also protects the conductive layers from the environment during operation (such as from, corrosion, etc.) Each pixel 926, 928 and 930 corresponds to at least one column interconnect and at least one row interconnect. The cross-sectional view of FIG. 9 is taken along a row in an array of pixels (such as in FIG. 10), and therefore each of pixels 926, 928 and 930 shares the same row interconnect 906. The row interconnect 906 electrically connects to a conductive spacer 904 and flexible contact 912 on a substrate 922 in a display area 920. The conductive spacer 912 also electrically connects to a routing interconnect 914 on the aperture plate 924 in the display area 920. By locating the conductive spacer 912 inside of the display area 920 rather than within a bezel area, the bezel area can be reduced or eliminated. The flexible contact 912 allows the conductive spacer 904 to maintain an electrical connection between the interconnects even when the space between the aperture plate and the substrate increases or decreases. A flexible contact may be arranged in various configurations including one or extendable members or fingers. Each of the extendable members may extend in any direction. An extendable member may be configured as an arch. An extendable member may include a curved portion. An extendable member may be arranged to contact one or more spacers or one or more extendable members or fingers may contact a pad or multiple pads.

An insulating layer 938 is formed on the aperture plate between the routing interconnect 914 and MEMS light modulators 902. In the display apparatus 900, the routing interconnect 914 runs through the display area 920 on aperture plate 924 and electrically connects with the conductive spacer 912 within the display area 920. By running the routing interconnect 914 through the display area 920 and electrically connecting the routing interconnect 914 to the row interconnect 906 via conductive spacer 912 within the display area 920, instead of the bezel area, the size of bezel area can be reduced or eliminated. The routing interconnect 914 may electrically connect to a row driver (not shown).

FIG. 10 shows a plan view of an example display apparatus 1000 illustrating row, column and routing interconnects. The display apparatus 1000 includes an array of pixels 1004 located within a display area 1020. The display apparatus 1000 corresponds to the cross-sectional view of the display apparatus 900, from the perspective of cross-section line 1002. The display apparatus 900 corresponds to the cross-section of the display area 1020 and of three pixels out of the array of pixels 1004. As described with respect to FIG. 9, the routing interconnects 1014 are formed on the aperture plate and run through the display area 1020. The routing interconnects 1014 correspond to routing interconnect 914 of display device 900. In contrast with display devices 600 of FIG. 6 and 800 of FIG. 8, the connection points 1012 between the routing interconnects 1014 and the conductive spacers 912 are located within the display area 1020 and not within the bezel area 1018. By locating the connection points 1012 between the routing interconnects 1014, the conductive spacers 912 and the row interconnects 906 within the display area 1020, the bezel area 1018 can be reduced or eliminated. Also, by locating the connection points 1012 between the routing interconnects 1014 the connection points are more protected from the surrounding environment. Furthermore, locating the connection points 1012 in the display area 1020 reduces the length of the interconnect from the driver thereby lowering interconnect resistance. In addition it may be possible to have additional routing connections from the driver to the specific row line thereby reducing the distance of the farthest pixels to the routing connector and reducing the interconnect resistance.

Each pixel in the display area 1020 includes a row interconnect 1006 and a column interconnect 1008, 1032 and 1034. The row interconnect 1006 and the column interconnects 1008, 1032 and 1034 correspond to the row interconnect 906 and column interconnects 908, 932 and 934 of the display device 900. Each of the row interconnects 1006 in the array 1004 electrically connect to the routing interconnects 1014 via an electrically conductive spacer and a contact pad 1012 (as described with respect to FIG. 9 above) within the display area 1020. The conductive spacers and the contact pads 1012 are staggered throughout the display area 1020.

The routing interconnects 1014 electrically connect to a row driver 1024. The routing interconnects 1014, fabricated on the aperture plate, may electrically connect to row driver interconnects via conductive spacer, such as the conductive spacer 1012. The row driver 1024 may be fabricated on the substrate. The column interconnects 1008, 1032 and 1034 electrically connect to a column driver 1026. The column driver 1026 may be fabricated on the substrate. As shown in FIG. 10, the row driver 1024 and the column driver 1026 are located outside of the display area 1020 and on one side of the display area 1020. However, the row driver 1024 and the column driver 1026 may be located anywhere outside of display area 1020 (i.e., above, below, to the left or to the right), or may be located in a combination of positions outside of the display area 1020. In some implementations, the row driver 1024 and the column driver 1026 may be fabricated on the aperture plate. In some implementation the row driver 1024 and the column driver 1026 may be located on a flexible printed circuits (FPC). If through-glass vias are implemented then the row driver 1024 and the column driver 1026 may be located on the back side of either the backplane or the aperture plate. In some implementations the row driver 1024 and the column driver 1026 are implemented with TFTs, and may be located on the backplane.

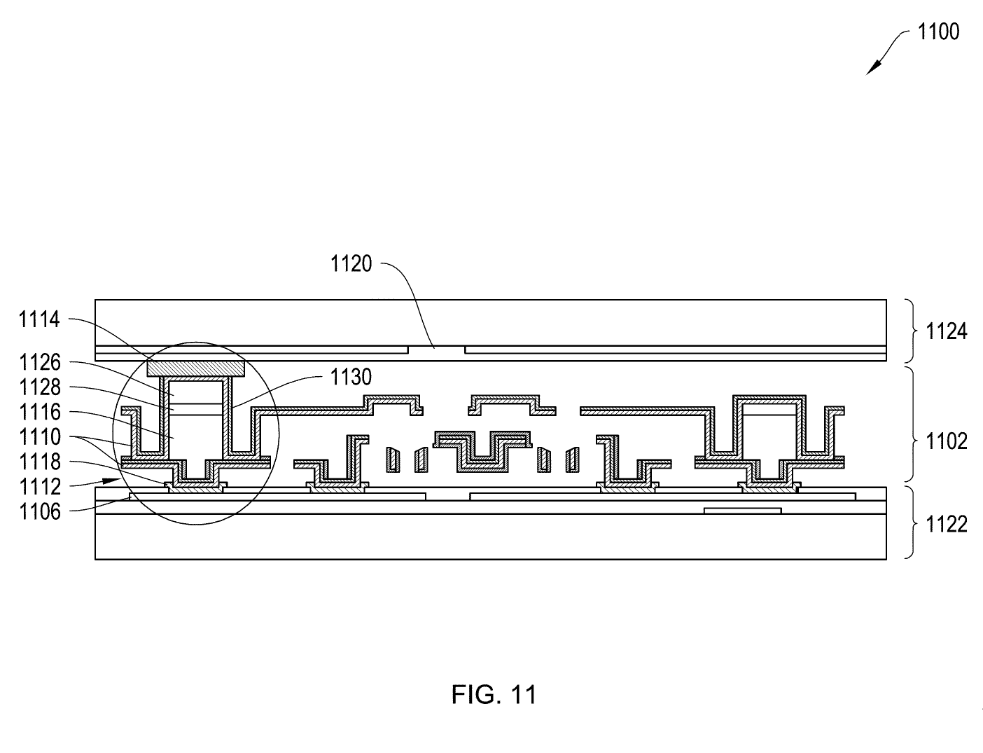

FIGS. 11-15 show various examples of example conductive spacer designs and related fabrication processes. The examples of conductive spacers shown in FIGS. 11-15 may be used as the conductive spacers shown and described with respect to FIGS. 5-10. FIG. 11 is a cross-sectional view of a display apparatus 1100 illustrating a conductive spacer 1112 separating the substrate 1122 from the aperture plate 1124. The conductive spacer 1112 creates an electrical connection between at least one interconnect 1106 on the substrate 1122 and at least one interconnect 1114 on the aperture plate 1124. In some implementations, the interconnect 1114 is a routing interconnect, as described with respect to FIGS. 5-10. In some implementations, the interconnect 1114 is a row interconnect or a column interconnect running through an array of pixels. As shown, in FIG. 11, the conductive spacer 1112 structure directly connects to the interconnect 1106 on the substrate 1122 and to the interconnect 1114 on the aperture plate 1124. An aperture slot 1120 allows light to pass through the aperture plate 1124. The conductive spacer 1112 is made up of photoresist including a first layer of resist 1126 layered on top of a second layer of resist 1128 layered on top of a layer of anchor resist 1116. The resist, or plug of resist, can be coated with a conductive material 1110. For example the conductive material 1110 may be doped amorphous silicon. A layer of Ti 1130 may be coated on top of the conductive material 1110. The layer 1130 may be arranged continuously on the top of the spacer 1112. Any metal layers can be used for the layer 1130 such as, without limitation, Ta, TaNx, Ti, TiNx, Mo, MoNx, Al alloy, and multiple layers of any conductive layers. The conductive spacer 1112 electrically connects to the conductive interconnect 1106 through a conductive via 1118. Thus, an electrical conduction path is created between the interconnect 1106 and the buss line 1114.

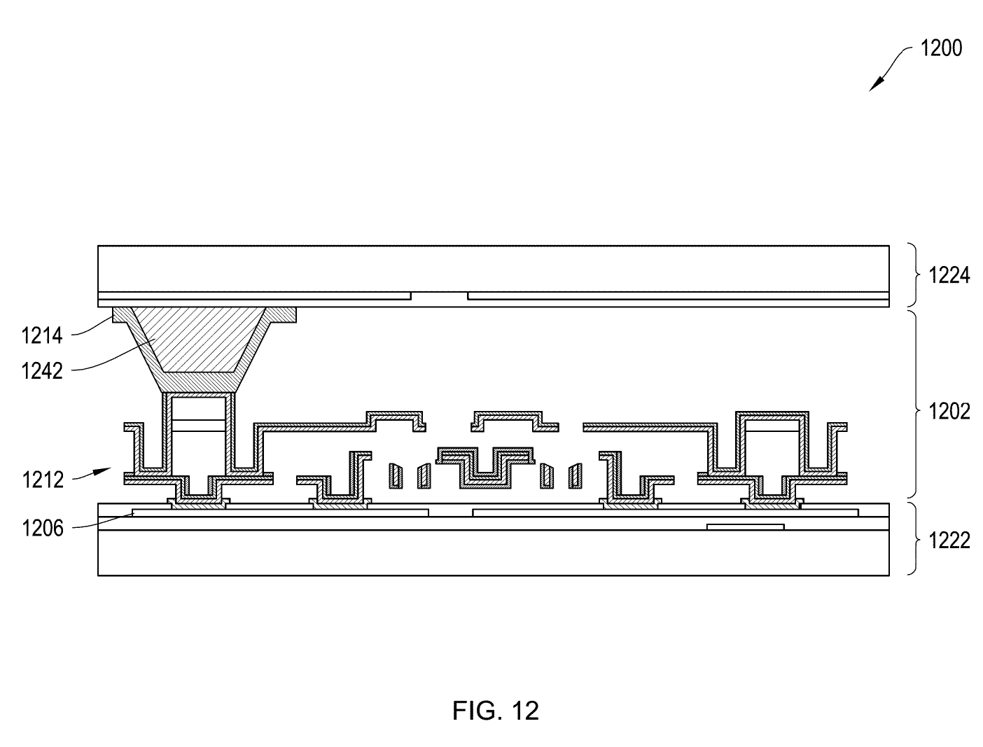

FIG. 12 shows a cross-sectional view of an example display apparatus 1200 illustrating a conductive spacer 1212 separating a substrate 1222 from an aperture plate 1224. The conductive spacer 1212 creates an electrical connection between at least one interconnect 1206 on the substrate 1222 and at least one interconnect 1214 on the aperture plate 1224. In some implementations, the interconnect 1214 is a routing interconnect, as described with respect to FIGS. 5-10. In some implementations, the interconnect 1214 is a row interconnect or a column interconnect running through an array of pixels. As shown, in FIG. 12, an elastic polymer 1242 is located between the aperture plate 1224 and the interconnect 1214. The elastic polymer 1242 can improve the electrical and physical contact between the conductive spacer 1212 and the interconnect 1214. For example, the elastic polymer 1242 allows for some adjustment when the vertical or lateral spacing between the plates 1224 and 1222 shifts due to forces such as mechanical pressure, temperature change, etc. The elastic polymer 1242 can follow the shifts between the plates 1224 and 1222 and maintain contact between the conductive spacer 1212 and the interconnect 1214.

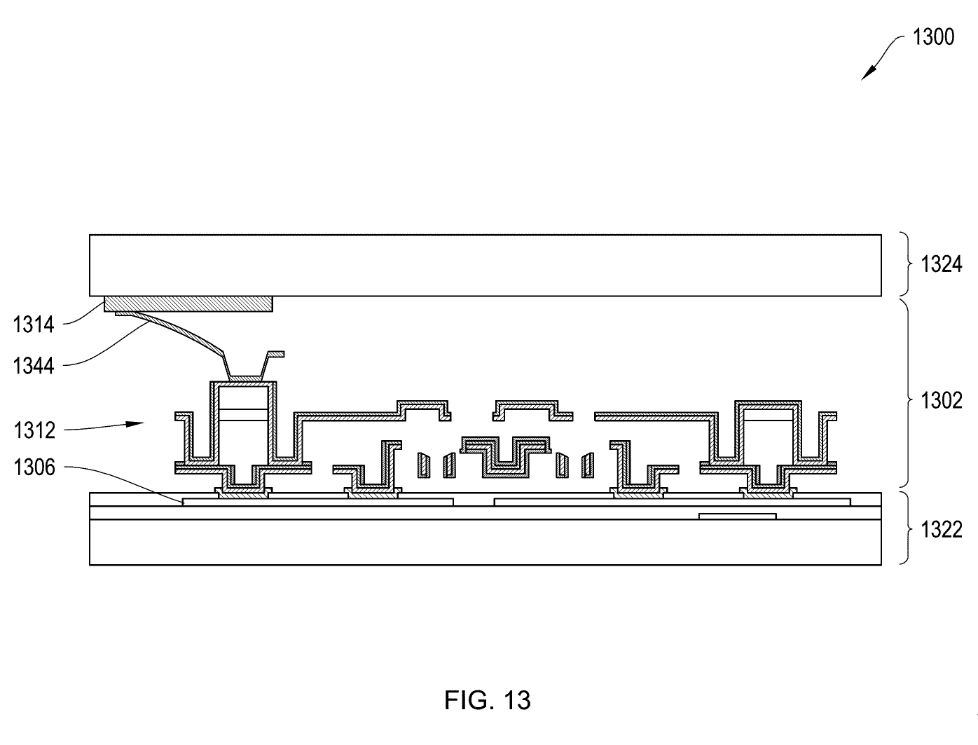

FIG. 13 shows a cross-sectional view of an example display apparatus 1300 illustrating a conductive spacer 1312 separating a substrate 1322 from an aperture plate 1324. The conductive spacer 1312 creates an electrical connection between at least one interconnect 1306 on the substrate 1322 and at least one interconnect 1314 on the aperture plate 1324. In some implementations, the interconnect 1314 is a routing interconnect, as described with respect to FIGS. 5-10. In some implementations, the interconnect 1314 is a row interconnect or a column interconnect running through an array of pixels. As shown, in FIG. 13, a flexible contact 1344 is coupled to a conductive spacer 1312, making electrical contact between the conductive spacer 1344 and the interconnect 1314. The flexible contact 1344 can improve the electrical and physical contact between the conductive spacer 1312 and the interconnect 1314. The space between the aperture plate 1324 and the substrate 1322 is not stable and the flexible contact 1344 allows the conductive spacer 1344 to maintain an electrical connection between the interconnects 1306 and 1314 even when the space between the aperture plate 1324 and the substrate 1322 increases or decreases. The flexible contact 1344 may be made of thin film metal, doped amorphous silicon, multi-layers of conductive film and dielectric film, or out of another suitable material. The flexible contact 1344 is designed to be launched up after release during the fabrication process. In some implementations, the flexible contact 1344 allows for cell deformation during assembly, handling and operation of the display device over wider temperature ranges. The flexible contact 1344 can follow large changes in space between the aperture plate 1324 and the substrate 1322 and maintain contact between the interconnects 1306 and 1314.

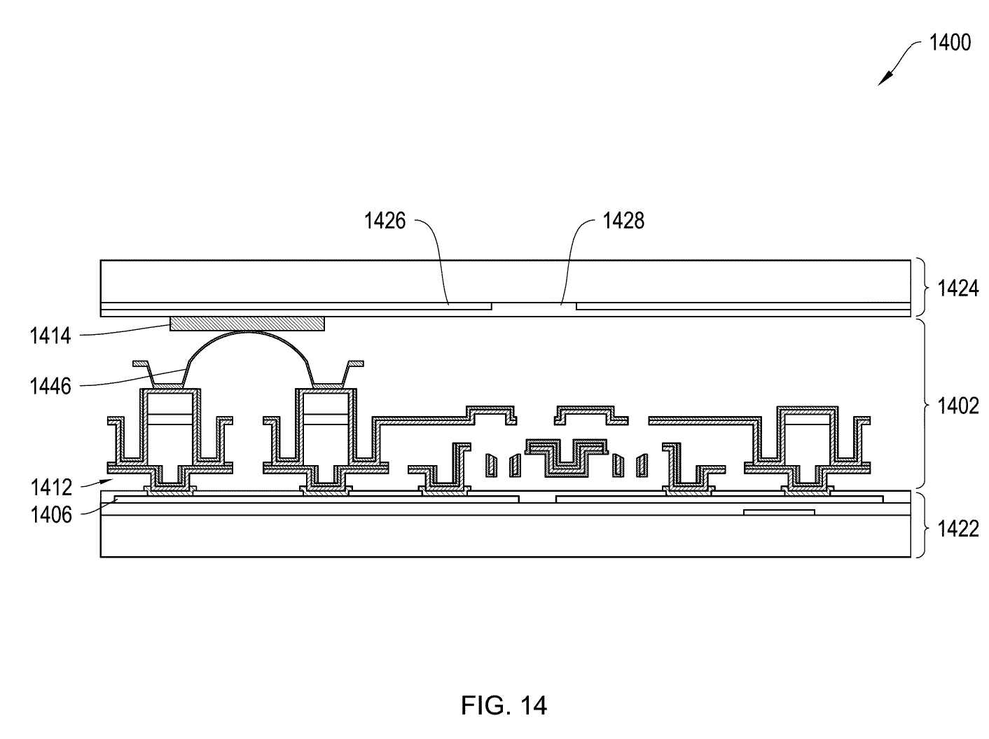

FIG. 14 shows a cross-sectional view of an example display apparatus 1400 illustrating conductive spacers 1412 making an electrical connection between a substrate 1422 and an aperture plate 1424. The aperture plate 1424 includes a black matrix layer 1426 and an aperture slot 1428. The aperture slot 1428 allows light to pass through the aperture plate 1424. In FIG. 14, there are two conductive spacers 1412 for the given pixel. Two or more conductive spacers may help prevent failure in the display device. The two conductive spacers 1412 may be implemented to provide as a failure mechanism, as in having one contact be a backup if another fails. In addition, the structure of the display apparatus 1400 may be more robust during manufacturing. Having two conductive spacers 1412 provides a better spring force to push against the aperture plate 1424 and provide a better electrical connection. Furthermore, the two conductive spacers 1412 provide a wider contact area than a single connector and provide the ability to connect to two or more spacer connectors. In some implementations, more than two conductive spacers may be used in each pixel. The conductive spacers 1412 create an electrical connection between at least one interconnect 1406 on the substrate 1422 and at least one interconnect 1414 on the aperture plate 1424. In some implementations, the interconnect 1414 is a routing interconnect, as described with respect to FIGS. 5-10. In some implementations, the interconnect 1414 is a row interconnect or a column interconnect running through an array of pixels. As shown, in FIG. 14, a flexible contact 1446 is coupled to the conductive spacers 1412, making electrical contact between the conductive spacers 1412 and the interconnect 1414. The flexible contact 1446 can improve the electrical and physical contact between the conductive spacers 1412 and the interconnect 1414. In some implementations, the space between the aperture plate 1424 and the substrate 1422 is not stable and the flexible contact 1446 allows the conductive spacer 1412 to maintain an electrical connection between the interconnects 1406 and 1414 even when the space between the aperture plate 1424 and the substrate 1422 increases or decreases. The flexible contact 1446 may be made of thin film metal, doped amorphous silicon, multi-layers of conductive film and dielectric film, or out of another suitable material. The flexible contact 1446 is designed to be launched up after release during the fabrication process.

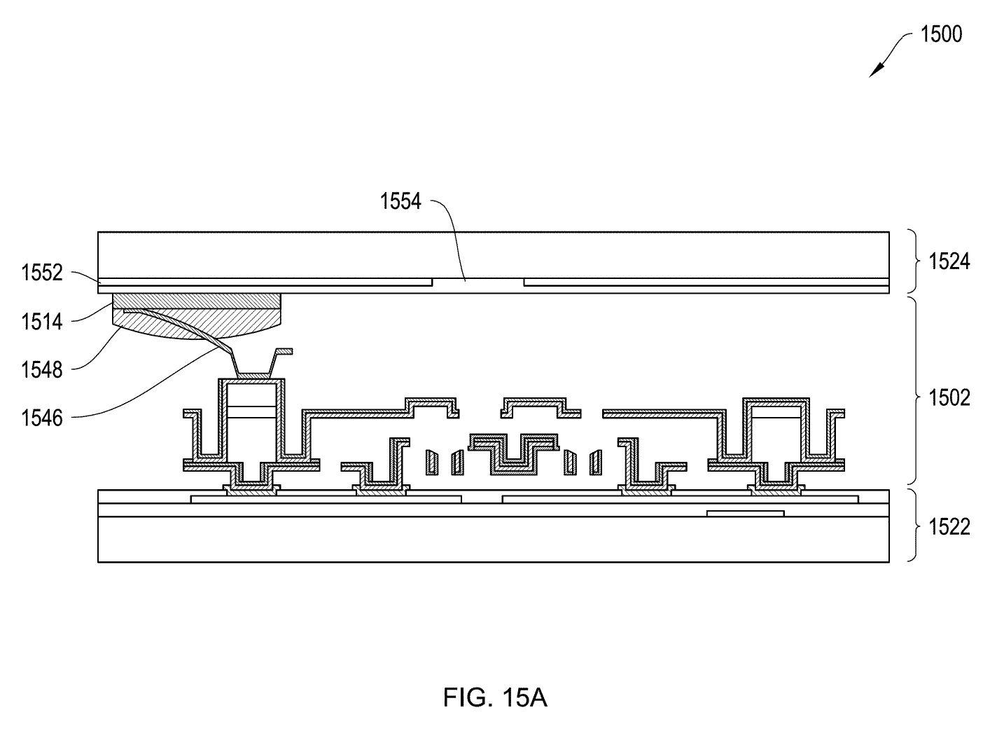

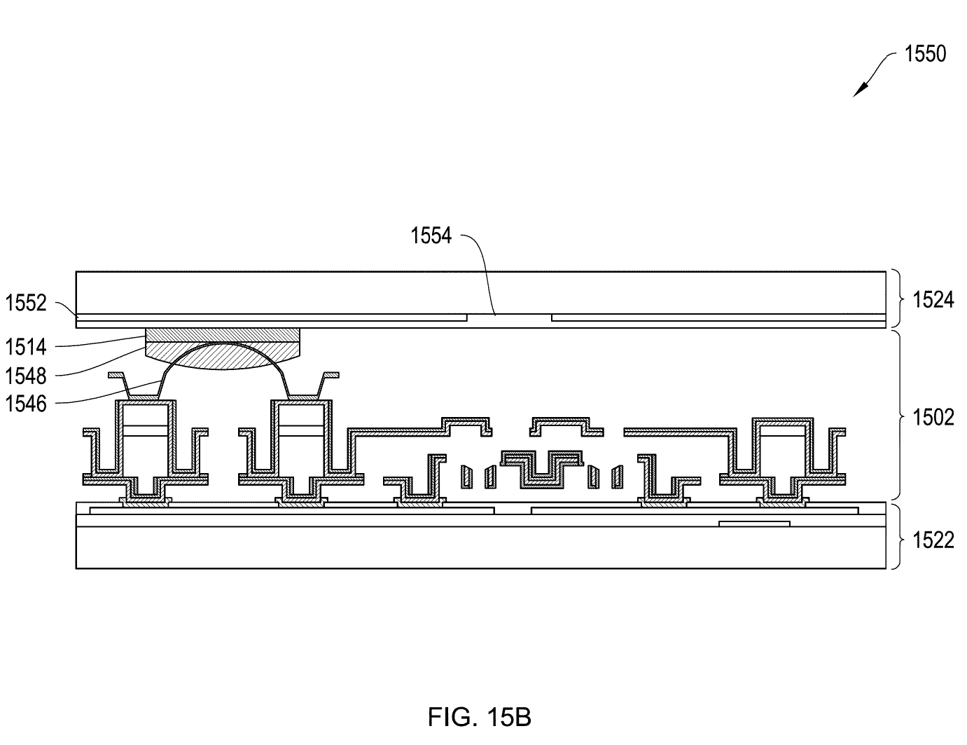

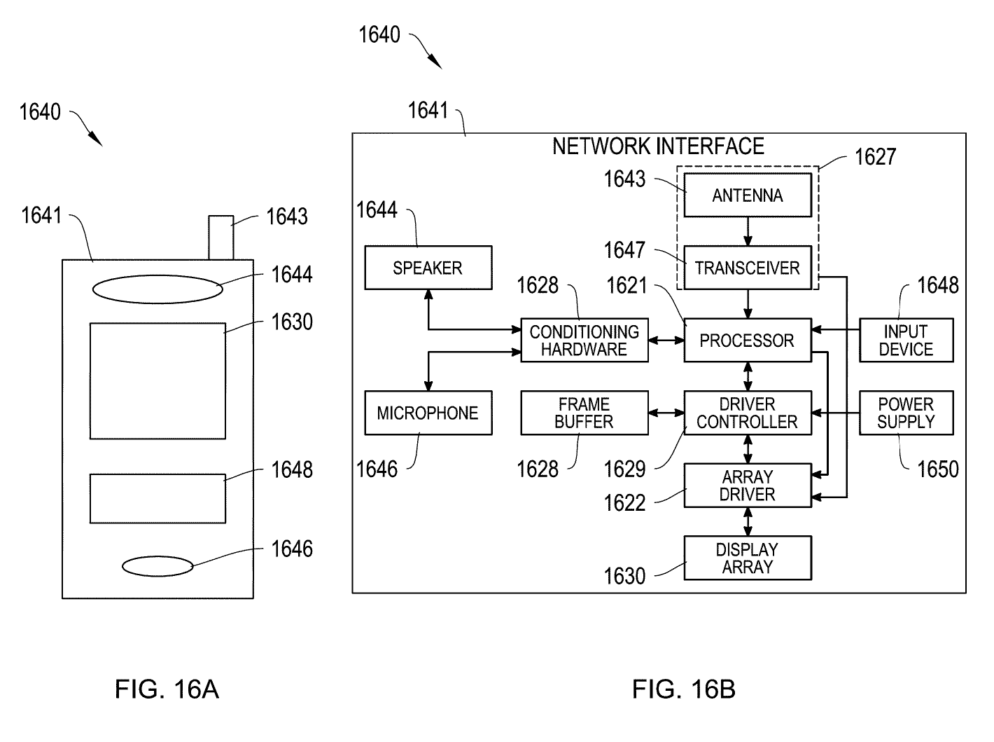

FIGS. 15A and 15B show cross-sectional views of example display apparatuses 1500 and 1550 illustrating conductive spacers making an electrical connection between a substrate 1522 and an aperture plate 1524. The aperture plate 1524 includes a black matrix layer 1552 and an aperture slot 1554. The aperture slot 1554 allows light to pass through the aperture plate 1524. The display apparatus 1550 includes two conductive spacers per pixel, while the display apparatus 1500 includes one conductive spacer for a given pixel. Display apparatus 1500 and 1550 also includes a eutectic metal layer 1548 for securing contact between the flexible metal contact 1546 and the interconnect 1514. The eutectic metal layer 1548 may include Indium, solder, or another suitable low temperature melting point metal or metal alloy. The eutectic metal layer 1548 may connect to the flexible contact 1546 during a reflow process after the eutectic metal 1548 has been elevated to a temperature above its liquid phase temperatures, submerging the flexible contact 1546 into the liquid metal, and letting the metal re-solidify by lowering temperature. FIGS. 16A and 16B show system block diagrams of an example display device 1640 that includes a plurality of display elements. The display device 1640 can be, for example, a smart phone, a cellular or mobile telephone. However, the same components of the display device 1640 or slight variations thereof are also illustrative of various types of display devices such as televisions, computers, tablets, e-readers, hand-held devices and portable media devices.

The display device 1640 includes a housing 1641, a display 1630, an antenna 1643, a speaker 1645, an input device 1648 and a microphone 1646. The housing 1641 can be formed from any of a variety of manufacturing processes, including injection molding, and vacuum forming. In addition, the housing 1641 may be made from any of a variety of materials, including, but not limited to: plastic, metal, glass, rubber and ceramic, or a combination thereof. The housing 1641 can include removable portions (not shown) that may be interchanged with other removable portions of different color, or containing different logos, pictures, or symbols.

The display 1630 may be any of a variety of displays, including a bi-stable or analog display, as described herein. The display 1630 also can be capable of including a flat-panel display, such as plasma, electroluminescent (EL) displays, OLED, super twisted nematic (STN) display, LCD, or thin-film transistor (TFT) LCD, or a non-flat-panel display, such as a cathode ray tube (CRT) or other tube device. In addition, the display 1630 can include a mechanical light modulator-based display, as described herein.

The components of the display device 1640 are schematically illustrated in FIG. 16B. The display device 1640 includes a housing 1641 and can include additional components at least partially enclosed therein. For example, the display device 1640 includes a network interface 1627 that includes an antenna 1643 which can be coupled to a transceiver 1647. The network interface 1627 may be a source for image data that could be displayed on the display device 1640. Accordingly, the network interface 1627 is one example of an image source module, but the processor 1621 and the input device 48 also may serve as an image source module. The transceiver 1647 is connected to a processor 1621, which is connected to conditioning hardware 1652. The conditioning hardware 1652 may be capable of conditioning a signal (such as filter or otherwise manipulate a signal). The conditioning hardware 1652 can be connected to a speaker 1645 and a microphone 1646. The processor 1621 also can be connected to an input device 48 and a driver controller 1629. The driver controller 1629 can be coupled to a frame buffer 1628, and to an array driver 1622, which in turn can be coupled to a display array 1630. One or more elements in the display device 1640, including elements not specifically depicted in FIG. 16A, can be capable of functioning as a memory device and be capable of communicating with the processor 1621. In some implementations, a power supply 1650 can provide power to substantially all components in the particular display device 1640 design.

The network interface 1627 includes the antenna 1643 and the transceiver 1647 so that the display device 1640 can communicate with one or more devices over a network. The network interface 1627 also may have some processing capabilities to relieve, for example, data processing requirements of the processor 1621. The antenna 1643 can transmit and receive signals. In some implementations, the antenna 1643 transmits and receives RF signals according to any of the IEEE 16.11 standards, or any of the IEEE 802.11 standards. In some other implementations, the antenna 1643 transmits and receives RF signals according to the Bluetooth® standard. In the case of a cellular telephone, the antenna 1643 can be designed to receive code division multiple access (CDMA), frequency division multiple access (FDMA), time division multiple access (TDMA), Global System for Mobile communications (GSM), GSM/General Packet Radio Service (GPRS), Enhanced Data GSM Environment (EDGE), Terrestrial Trunked Radio (TETRA), Wideband-CDMA (W-CDMA), Evolution Data Optimized (EV-DO), 1×EV-DO, EV-DO Rev A, EV-DO Rev B, High Speed Packet Access (HSPA), High Speed Downlink Packet Access (HSDPA), High Speed Uplink Packet Access (HSUPA), Evolved High Speed Packet Access (HSPA+), Long Term Evolution (LTE), AMPS, or other known signals that are used to communicate within a wireless network, such as a system utilizing 3G, 4G or 5G, or further implementations thereof, technology. The transceiver 1647 can pre-process the signals received from the antenna 1643 so that they may be received by and further manipulated by the processor 1621. The transceiver 1647 also can process signals received from the processor 1621 so that they may be transmitted from the display device 1640 via the antenna 1643.

In some implementations, the transceiver 1647 can be replaced by a receiver. In addition, in some implementations, the network interface 1627 can be replaced by an image source, which can store or generate image data to be sent to the processor 1621. The processor 1621 can control the overall operation of the display device 1640. The processor 1621 receives data, such as compressed image data from the network interface 1627 or an image source, and processes the data into raw image data or into a format that can be readily processed into raw image data. The processor 1621 can send the processed data to the driver controller 1629 or to the frame buffer 1628 for storage. Raw data typically refers to the information that identifies the image characteristics at each location within an image. For example, such image characteristics can include color, saturation and gray-scale level.

The processor 1621 can include a microcontroller, CPU, or logic unit to control operation of the display device 1640. The conditioning hardware 1652 may include amplifiers and filters for transmitting signals to the speaker 1645, and for receiving signals from the microphone 1646. The conditioning hardware 1652 may be discrete components within the display device 1640, or may be incorporated within the processor 1621 or other components.

The driver controller 1629 can take the raw image data generated by the processor 1621 either directly from the processor 1621 or from the frame buffer 1628 and can re-format the raw image data appropriately for high speed transmission to the array driver 1622. In some implementations, the driver controller 1629 can re-format the raw image data into a data flow having a raster-like format, such that it has a time order suitable for scanning across the display array 1630. Then the driver controller 1629 sends the formatted information to the array driver 1622. Although a driver controller 1629 is often associated with the system processor 1621 as a stand-alone Integrated Circuit (IC), such controllers may be implemented in many ways. For example, controllers may be embedded in the processor 1621 as hardware, embedded in the processor 1621 as software, or fully integrated in hardware with the array driver 1622.

The array driver 1622 can receive the formatted information from the driver controller 1629 and can re-format the video data into a parallel set of waveforms that are applied many times per second to the hundreds, and sometimes thousands (or more), of leads coming from the display's x-y matrix of display elements. In some implementations, the array driver 1622 and the display array 1630 are a part of a display module. In some implementations, the driver controller 1629, the array driver 1622, and the display array 1630 are a part of the display module.

In some implementations, the driver controller 1629, the array driver 1622, and the display array 1630 are appropriate for any of the types of displays described herein. For example, the driver controller 1629 can be a conventional display controller or a bi-stable display controller (such as a mechanical light modulator display element controller). Additionally, the array driver 1622 can be a conventional driver or a bi-stable display driver (such as a mechanical light modulator display element controller). Moreover, the display array 1630 can be a conventional display array or a bi-stable display array (such as a display including an array of mechanical light modulator display elements). In some implementations, the driver controller 1629 can be integrated with the array driver 1622. Such an implementation can be useful in highly integrated systems, for example, mobile phones, portable-electronic devices, watches or small-area displays.

In some implementations, the input device 1648 can be capable of allowing, for example, a user to control the operation of the display device 1640. The input device 1648 can include a keypad, such as a QWERTY keyboard or a telephone keypad, a button, a switch, a rocker, a touch-sensitive screen, a touch-sensitive screen integrated with the display array 1630, or a pressure- or heat-sensitive membrane. The microphone 1646 can be configured as an input device for the display device 1640. In some implementations, voice commands through the microphone 1646 can be used for controlling operations of the display device 1640. Additionally, in some implementations, voice commands can be used for controlling display parameters and settings.

The power supply 1650 can include a variety of energy storage devices. For example, the power supply 1650 can be a rechargeable battery, such as a nickel-cadmium battery or a lithium-ion battery. In implementations using a rechargeable battery, the rechargeable battery may be chargeable using power coming from, for example, a wall socket or a photovoltaic device or array. Alternatively, the rechargeable battery can be wirelessly chargeable. The power supply 1650 also can be a renewable energy source, a capacitor, or a solar cell, including a plastic solar cell or solar-cell paint. The power supply 50 also can be capable of receiving power from a wall outlet.

In some implementations, control programmability resides in the driver controller 1629 which can be located in several places in the electronic display system. In some other implementations, control programmability resides in the array driver 1622. The above-described optimization may be implemented in any number of hardware and/or software components and in various configurations.

As used herein, a phrase referring to “at least one of” a list of items refers to any combination of those items, including single members. As an example, “at least one of: a, b, or c” is intended to cover: a, b, c, a-b, a-c, b-c, and a-b-c.

The various illustrative logics, logical blocks, modules, circuits and algorithm steps described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and steps described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor also may be implemented as a combination of computing devices, such as a combination of a DSP and a microprocessor, a plurality of microprocessors, one or more microprocessors in conjunction with a DSP core, or any other such configuration. In some implementations, particular steps and methods may be performed by circuitry that is specific to a given function.

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also can be implemented as one or more computer programs, i.e., one or more modules of computer program instructions, encoded on a computer storage media for execution by, or to control the operation of, data processing apparatus.

If implemented in software, the functions may be stored on or transmitted over as one or more instructions or code on a computer-readable medium. The steps of a method or algorithm disclosed herein may be implemented in a processor-executable software module which may reside on a computer-readable medium. Computer-readable media includes both computer storage media and communication media including any medium that can be enabled to transfer a computer program from one place to another. A storage media may be any available media that may be accessed by a computer. By way of example, and not limitation, such computer-readable media may include RAM, ROM, EEPROM, CD-ROM or other optical disk storage, magnetic disk storage or other magnetic storage devices, or any other medium that may be used to store desired program code in the form of instructions or data structures and that may be accessed by a computer. Also, any connection can be properly termed a computer-readable medium. Disk and disc, as used herein, includes compact disc (CD), laser disc, optical disc, digital versatile disc (DVD), floppy disk, and blu-ray disc where disks usually reproduce data magnetically, while discs reproduce data optically with lasers. Combinations of the above also may be included within the scope of computer-readable media. Additionally, the operations of a method or algorithm may reside as one or any combination or set of codes and instructions on a machine readable medium and computer-readable medium, which may be incorporated into a computer program product.

Various modifications to the implementations described in this disclosure may be readily apparent to those having ordinary skill in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein.

Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of, e.g., an IMOD display element as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, a person having ordinary skill in the art will readily recognize that such operations need not be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. A display, comprising:
a substrate including a plurality of pixels, each respective pixel including:
at least one light modulator;
at least one row interconnect; and
at least one column interconnect;
an aperture plate including at least one routing interconnect formed thereon; and
a conductive spacer coupled between the substrate and the aperture plate, the conductive spacer being an electrical connection between the at least one row interconnect and the at least one routing interconnect.

2. The display of claim 1, wherein the substrate includes at least one routing interconnect.

3. The display of claim 1, wherein each of the at least one routing interconnects is formed on the aperture plate.

4. The display of claim 1, further comprising a bezel area, wherein the at least one routing interconnect runs through the bezel area.

5. The display of claim 4, wherein the conductive spacer makes electrical contact with the at least one routing interconnect in the bezel area.

6. The display of claim 1, further comprising a display area, wherein the at least one routing interconnect runs through the display area.

7. The display of claim 6, wherein the conductive spacer makes electrical contact with the at least one routing interconnect in the display area.

8. The display of claim 1, wherein at least one interconnect is formed on the aperture plate.

9. The display of claim 1, wherein the at least one row interconnect is electrically coupled to a row driver and at least one column interconnect is electrically coupled to a column driver.

10. The display of claim 9, wherein the routing interconnect electrically couples the at least one row interconnect to the row driver.

11. The display of claim 9, wherein the routing interconnect electrically couples the at least one column interconnect to the column driver.

12. The display of claim 1, wherein the routing interconnect electrically couples at least one row interconnect to at least one other row interconnect.

13. The display of claim 1, wherein the routing interconnect electrically couples at least one column interconnect to at least one other column interconnect.

14. The display of claim 1, wherein the aperture plate includes at least one of an elastic polymer and a eutectic metal.

15. The display of claim 1, wherein the conductive spacer includes a flexible contact.

16. The display of claim 1, wherein a respective pixel includes at least two conductive spacers.

17. The display of claim 1 wherein the light modulator is a MEMS light modulator.

18. The display of claim 1, further comprising:
a processor capable of communicating with the display, the processor being capable of processing image data; and
a memory device capable of communicating with the processor.

19. The display of claim 18, further comprising:
a driver circuit capable of sending at least one signal to the display; and
a controller capable of sending at least a portion of the image data to the driver circuit.

20. The display of claim 18, further comprising:
an image source module capable of sending the image data to the processor, wherein the image source module includes at least one of a receiver, transceiver, and transmitter.

21. The display of claim 18, further comprising:
an input device capable of receiving input data and communicating the input data to the processor.

22. A display, comprising:
a substrate including a plurality of pixels, each respective pixel including:
at least one means for modulating light;
at least one means for electrically connecting a row of pixels; and
at least one means for electrically connecting a column of pixels;
an aperture plate means including at least one means for routing an electrical signal formed thereon; and
a conductive spacer means coupled between the substrate and the aperture plate means, the conductive spacer being in electrical connection between the at least one means for electrically connecting a row of pixels and the at least one means for routing an electrical signal.

23. The display of claim 22 wherein the substrate includes at least one means for routing an electrical signal.

24. The display of claim 22, wherein the at least one means for electrically connecting a row of pixels is electrically coupled to a means for providing a drive voltage and at least one means for electrically connecting a column of pixels is electrically coupled to the means for providing a drive voltage.

25. The display of claim 22, wherein the aperture plate includes at least one means for improving contact between the conductive spacer means and the means for routing an electrical signal.

26. The display of claim 22, wherein the conductive spacer means includes at least one flexible contact means.

27. The display of claim 22, wherein a respective pixel includes at least two conductive spacer means.

28. The display of claim 22 wherein the means for modulating light is a MEMS light modulator.
